(19) United States
(12) Patent Application Publication
(10) Pub. No.: US 2021/0366745 A1
(43) Pub. Date: Nov. 25, 2021

(54) THERMAL PROCESSING APPARATUS

(71) Applicant: SCREEN Holdings Co., Ltd., Kyoto (JP)

(72) Inventors: Masashi FURUKAWA, Kyoto-shi (JP); Shinichi KATO, Kyoto-shi (JP)

(21) Appl. No.: 17/320,272

(22) Filed: May 14, 2021

(30) Foreign Application Priority Data
May 19, 2020 (JP) 2020-087351

(51) Int. Cl. H01L 21/67; H05B 3/00; F27B 17/00; F27D 5/00; G01J 5/08; G01J 5/20

(52) U.S. Cl. CPC H01L 21/67248; H01L 21/67115; H01L 21/67103; H05B 3/0047; H05B 2203/037; F27D 5/0037; G01J 5/0853; G01J 5/20; H05B 2203/032; F27B 17/0025

(57) ABSTRACT

A thermal processing apparatus according to the present invention includes: a support including quartz and being for supporting a substrate from a first side within a chamber; a flash lamp disposed on a second side and being for heating the substrate by irradiating the substrate with a flash of light; a continuous illumination lamp disposed on the second side of the substrate and being for continuously heating the substrate; a light blocking member disposed to surround the substrate in plan view; and a radiation thermometer disposed on the first side of the substrate and being for measuring a temperature of the substrate, wherein the radiation thermometer measures the temperature of the substrate by receiving light at a wavelength capable of being transmitted through the support. Accuracy of measurement of the temperature of the substrate can thereby be increased.

### BACKGROUND OF THE INVENTION

### Field of the Invention

Technology disclosed in the description of the present application relates to thermal processing apparatuses.

### Description of the Background Art

In a process of manufacturing a semiconductor device, a step of introducing impurities is necessary to form a pn junction and the like within a laminar precision electronic substrate (hereinafter, also simply referred to as a “substrate”), such as a semiconductor wafer. Impurities are typically introduced by ion implantation and annealing thereafter.

If an annealing time is about a few seconds or more when implanted impurities are activated by annealing, the implanted impurities are diffused to a greater depth by heat, and, as a result, a junction is formed at a depth greater than a desired depth. This can interfere with favorable device formation.

As annealing technology for heating the semiconductor wafer in an extremely short time, flash lamp annealing (FLA) is attracting attention. FLA is thermal processing technology of irradiating an upper surface of the semiconductor wafer with a flash of light using a xenon flash lamp (a simple term “flash lamp” hereinafter refers to the xenon flash lamp) to raise the temperature on only the upper surface of the semiconductor wafer into which impurities have been implanted in an extremely short time (e.g., a few milliseconds or less).

Radiation spectral distribution of the xenon flash lamp is in an ultraviolet range to a near infrared range, has a shorter wavelength than that of a conventional halogen lamp, and is substantially coincident with a fundamental absorption band of a semiconductor wafer of silicon. Thus, in a case where the semiconductor wafer is irradiated with the flash of light from the xenon flash lamp, the temperature of the semiconductor wafer can rapidly be raised because less light is transmitted therethrough. Irradiation with a flash of light in an extremely short time of a few milliseconds or less is also found to be able to selectively raise the temperature of only a portion near the surface of the semiconductor wafer. A temperature rise in an extremely short time using the xenon flash lamp thus allows for activation of impurities without diffusing the impurities to a greater depth.

For example, Japanese Patent Application Laid-Open No. 2018-148201 discloses a flash lamp annealing apparatus that irradiates, after preheating a semiconductor wafer using halogen lamps arranged below a chamber with a quartz window therebetween, an upper surface of the semiconductor wafer with flashes of light from flash lamps arranged above the chamber with a quartz window therebetween.

In Japanese Patent Application Laid-Open No. 2018-148201 above, a radiation thermometer for measuring the temperature of the heated semiconductor wafer is disposed below the substrate. The radiation thermometer is required to receive light radiated from a lower surface of the semiconductor wafer while avoiding a wavelength region of light emitted from the halogen lamps arranged below the chamber, so that there is a limit to a measurable wavelength region and disposition of the radiation thermometer.

The limit can reduce measurement accuracy of the radiation thermometer.

### SUMMARY

The present invention is directed to a thermal processing apparatus.

One aspect of the present invention is a thermal processing apparatus including: a chamber for containing a substrate; a support for supporting the substrate from a first side within the chamber, the support including quartz; a flash lamp for heating the substrate by irradiating the substrate with a flash of light, the flash lamp being disposed on a second side of the substrate opposite the first side; a continuous illumination lamp for continuously heating the substrate, the continuous illumination lamp being disposed on the second side of the substrate; a light blocking member separating the first side and the second side of the substrate within the chamber, the light blocking member being disposed to surround the substrate in plan view; and at least one radiation thermometer for measuring a temperature of the substrate, the radiation thermometer being disposed on the first side of the substrate, wherein the radiation thermometer measures the temperature of the substrate by receiving light at a wavelength capable of being transmitted through the support. The radiation thermometer can sufficiently receive light radiated from the substrate, so that accuracy of measurement of the temperature of the substrate can be increased. Another aspect of the present invention is a thermal processing apparatus including: a support for supporting a substrate from a first side, the support including quartz; a flash lamp for heating the substrate by irradiating the substrate with a flash of light, the flash lamp being disposed on a second side of the substrate opposite the first side; at least one LED lamp for continuously heating the substrate, the LED lamp being disposed on the first side of the substrate; a quartz window disposed between the flash lamp and the substrate and a quartz window disposed between the LED lamp and the support, the quartz windows including quartz; and at least one radiation thermometer for measuring a temperature of the substrate, the radiation thermometer being disposed on the first side of the substrate, wherein the radiation thermometer measures the temperature of the substrate by receiving light at a wavelength capable of being transmitted through the support.

The radiation thermometer can sufficiently receive light radiated from the substrate, so that accuracy of measurement of the temperature of the substrate can be increased.

Yet another aspect of the present invention is a thermal processing apparatus including: a support for supporting a substrate, the support including quartz; a flash lamp for heating the substrate by irradiating the substrate with a flash of light, the flash lamp being disposed on a second side of the substrate opposite a first side; a continuous illumination lamp for continuously heating the substrate, the continuous illumination lamp being disposed on the second side of the substrate; and at least one radiation thermometer for measuring a temperature of the substrate, the radiation thermometer being disposed on the first side of the substrate, wherein the support is disposed at least except at a location where the support intersects an optical axis of the radiation thermometer.

The radiation thermometer can sufficiently receive light radiated from the substrate, so that accuracy of measurement of the temperature of the substrate can be increased.

It is thus an object of the present invention to increase accuracy of measurement of the temperature of a substrate in a thermal processing apparatus.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing an example of a configuration of a thermal processing apparatus according to an embodiment;

FIG. 2 is an elevation view schematically showing the example of the configuration of the thermal processing apparatus according to the embodiment;

FIG. 3 is a cross-sectional view schematically showing a configuration of a thermal processing unit of the thermal processing apparatus according to the embodiment;

FIG. 4 is a perspective view illustrating appearance of a holding unit as a whole;

FIG. 5 is a plan view of a susceptor;

FIG. 6 is a cross-sectional view of the susceptor;

FIG. 7 is a plan view of a transfer mechanism;

FIG. 8 is a side view of the transfer mechanism;

FIG. 9 is a plan view illustrating arrangement of a plurality of halogen lamps of a heating unit;

FIG. 10 shows the relationship among a lower radiation thermometer, an upper radiation thermometer, and a controller;

FIG. 11 is a flowchart showing procedures of processing of a semiconductor wafer;

FIG. 12 shows a change in temperature on an upper surface of the semiconductor wafer;

FIG. 13 is a cross-sectional view schematically showing a configuration of a thermal processing unit according to an embodiment;

FIG. 14 shows examples of an emission wavelength of a flash lamp, an emission wavelength of a halogen lamp, and an absorption coefficient of the semiconductor wafer;

FIG. 15 is a cross-sectional view schematically showing a configuration of a thermal processing unit according to the embodiment;

FIG. 16 is a cross-sectional view schematically showing a configuration of a thermal processing unit according to an embodiment; and

FIG. 17 is a perspective view illustrating appearance of a holding unit as a whole.

### DESCRIPTION OF THE PREFERRED EMBODIMENTS

Embodiments will be described below with reference the accompanying drawings. In the embodiments below, detailed features and the like are shown for description of technology, but they are examples and are not necessary features to implement the embodiments.

The drawings are schematically shown, and configurations are omitted or simplified in the drawings as appropriate for the convenience of description. The sizes of and a positional relationship among configurations shown in different drawings are not necessarily accurate, and can be changed as appropriate. Hatching is sometimes applied to drawings other than a cross-sectional view, such as a plan view, for ease of understanding of the embodiments.

In description made below, similar components bear the same reference signs, and have similar names and functions. Detailed description thereof is thus sometimes omitted to avoid redundancy.

In description made below, an expression “comprising”, “including”, or “having” a certain component is not an exclusive expression excluding the presence of the other components unless otherwise noted.

In description made below, ordinal numbers, such as “first” and “second”, are used for the sake of convenience for ease of understanding of the embodiments, and an order and the like are not limited to an order represented by the ordinal numbers.

In description made below, expressions indicating relative or absolute positional relationships, such as “in one direction”, “along one direction”, “parallel”, “orthogonal”, “central”, “concentric”, and “coaxial”, include those exactly indicating the positional relationships and those in a case where an angle or a distance is changed within tolerance or to the extent that similar functions can be obtained unless otherwise noted.

In description made below, expressions indicating equality, such as “same”, “equal”, “uniform”, and “homogeneous”, include those indicating exact equality and those in a case where there is a difference within tolerance or to the extent that similar functions can be obtained unless otherwise noted.

In description made below, terms representing specific locations or directions, such as “upper”, “lower”, “left”, “right”, “side”, “bottom”, “front”, and “back”, are used for the sake of convenience for ease of understanding of the embodiments, and do not relate to locations or directions in actual use.

In description made below, an expression “an upper surface of . . . ” or “a lower surface of . . . ” includes not only an upper surface or a lower surface of an objective component itself but also a state of another component being formed on the upper surface or the lower surface of the objective component. That is to say, an expression “A provided on an upper surface of B” does not prevent another component “C” from being interposed between A and B, for example.

### First Embodiment

A thermal processing apparatus and a thermal processing method according to the present embodiment will be described below.

<Configuration of Thermal Processing Apparatus>

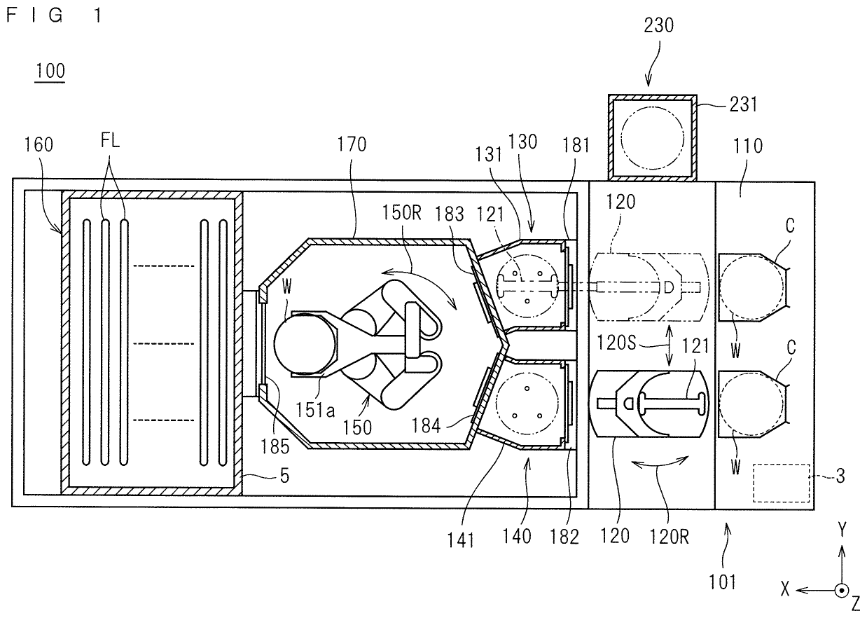

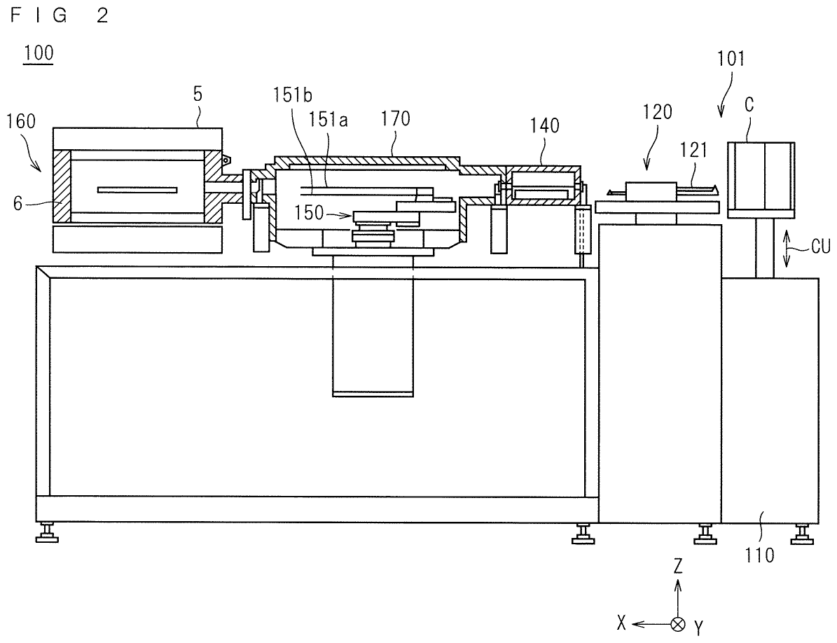

FIG. 1 is a plan view schematically showing an example of a configuration of a thermal processing apparatus 100 according to the present embodiment. FIG. 2 is an elevation view schematically showing the example of the configuration of the thermal processing apparatus 100 according to the present embodiment.

As illustrated in FIG. 1, the thermal processing apparatus 100 is a flash lamp annealing apparatus for heating a disk-shaped semiconductor wafer W as a substrate by irradiating the semiconductor wafer W with a flash of light.

The size of the semiconductor wafer W to be processed is not particularly limited, but the semiconductor wafer W is a circular semiconductor wafer having a diameter of 300 mm or 450 mm, for example.

As illustrated in FIGS. 1 and 2, the thermal processing apparatus 100 includes: an indexer unit 101 for transporting an unprocessed semiconductor wafer W from the outside to the inside of the apparatus, and transporting a processed semiconductor wafer W to the outside of the apparatus; an alignment unit 230 for positioning the unprocessed semiconductor wafer W; two cooling units, namely, a cooling unit 130 and a cooling unit 140, for cooling a heated semiconductor wafer W; a thermal processing unit 160 for flash heating the semiconductor wafer W; and a transport robot 150 for transferring the semiconductor wafer W to and from the cooling unit 130, the cooling unit 140, and the thermal processing unit 160.

The thermal processing apparatus 100 also includes a controller 3 for controlling an operation mechanism provided in each of the above-mentioned processing units and the transport robot 150 to proceed with flash heating of the semiconductor wafer W.

The indexer unit 101 includes a load port 110 on which a plurality of carriers C (two carriers C in the present embodiment) are mounted side by side, and a transfer robot 120 for taking the unprocessed semiconductor wafer W out of each of the carriers C, and storing the processed semiconductor wafer W in each of the carriers C.

A carrier C containing the unprocessed semiconductor wafer W is transported by an automated guide vehicle (AGV), an overhead hoist transfer (OHT), and the like, and is mounted on the load port 110, and a carrier C containing the processed semiconductor wafer W is taken away from the load port 110 by the AGV.

On the load port 110, the carriers C are each configured to be movable upward and downward as shown by an arrow CU of FIG. 2 so that the transfer robot 120 can take any semiconductor wafer W into and out of the carrier C.

Each of the carriers C may be in the form of not only a front opening unified pod (FOUP) for storing the semiconductor wafer W in an enclosed space but also a standard mechanical interface (SMIF) pod or an open cassette (OC) for exposing the stored semiconductor wafer W to outside air.

The transfer robot 120 is slidably movable as shown by an arrow 120S of FIG. 1, and can perform rotation operation as shown by an arrow 120R of FIG. 1 and upward and downward operation. The transfer robot 120 thus takes the semiconductor wafer W into and out of each of the two carriers C, and transfers the semiconductor wafer W to and from the alignment unit 230 and the two cooling units 130 and 140.

The transfer robot 120 takes the semiconductor wafer W into and out of each of the carriers C through slide movement of a hand 121 and upward and downward movement of the carrier C. The transfer robot 120 transfers the semiconductor wafer W to and from the alignment unit 230 or the cooling unit 130 (cooling unit 140) through the slide movement of the hand 121 and the upward and downward operation of the transfer robot 120.

The alignment unit 230 is connected to a side of the indexer unit 101 along a Y-axis direction. The alignment unit 230 is a processing unit for rotating the semiconductor wafer W in a horizontal plane to orient the semiconductor wafer W in a direction suitable for flash heating. The alignment unit 230 is configured to include, within an alignment chamber 231 as a housing of an aluminum alloy, a mechanism for rotating the semiconductor wafer W while supporting the semiconductor wafer W in a horizontal position, a mechanism for optically detecting any notch or orientation flat formed at the periphery of the semiconductor wafer W, and the like.

The semiconductor wafer W is transferred to the alignment unit 230 by the transfer robot 120. The transfer robot 120 transfers the semiconductor wafer W to the alignment chamber 231 so that the center of the wafer is at a predetermined location.

The alignment unit 230 rotates the semiconductor wafer W received from the indexer unit 101 around an axis in the vertical direction with a center portion of the semiconductor wafer W as a rotation center, and optically detects the notch and the like to adjust the orientation of the semiconductor wafer W. The semiconductor wafer W whose orientation has been adjusted is taken out of the alignment chamber 231 by the transfer robot 120.

A transport chamber 170 containing the transport robot 150 is provided as a space for the transport robot 150 to transport the semiconductor wafer W. A chamber 6 of the thermal processing unit 160, a first cooling chamber 131 of the cooling unit 130, and a second cooling chamber 141 of the cooling unit 140 are connected in communication with respective three sides of the transport chamber 170.

The thermal processing unit 160 as a main component of the thermal processing apparatus 100 is a substrate processing unit for irradiating the semiconductor wafer W having undergone preheating (assist heating) with flashes of light from xenon flash lamps FL to flash heat the semiconductor wafer W. A configuration of the thermal processing unit 160 will further be described below.

The two cooling units 130 and 140 have substantially similar configurations. The cooling unit 130 and the cooling unit 140 each include, within the first cooling chamber 131 or the second cooling chamber 141 as a housing of an aluminum alloy, a cooling plate (not illustrated) of metal and a quartz plate (not illustrated) mounted on an upper surface of the cooling plate. The temperature of the cooling plate is adjusted to room temperature (approximately 23° C.) by a Peltier device or through thermostatic water circulation.

The semiconductor wafer W flash heated by the thermal processing unit 160 is transported to the first cooling chamber 131 or the second cooling chamber 141, and is mounted on the quartz plate to be cooled.

The first cooling chamber 131 and the second cooling chamber 141 are each located between the indexer unit 101 and the transport chamber 170, and connected to both the indexer unit 101 and the transport chamber 170.

The first cooling chamber 131 and the second cooling chamber 141 each have two openings for transporting the semiconductor wafer W to and from them. One of the two openings of the first cooling chamber 131 connected to the indexer unit 101 is openable and closable by a gate valve 181.

On the other hand, an opening of the first cooling chamber 131 connected to the transport chamber 170 is openable and closable by a gate valve 183. That is to say, the first cooling chamber 131 and the indexer unit 101 are connected to each other through the gate valve 181, and the first cooling chamber 131 and the transport chamber 170 are connected to each other through the gate valve 183.

The gate valve 181 is opened when the semiconductor wafer W is transferred between the indexer unit 101 and the first cooling chamber 131. The gate valve 183 is opened when the semiconductor wafer W is transferred between the first cooling chamber 131 and the transport chamber 170. The inside of the first cooling chamber 131 is an enclosed space when the gate valve 181 and the gate valve 183 are closed.

One of the two openings of the second cooling chamber 141 connected to the indexer unit 101 is openable and closable by a gate valve 182. On the other hand, an opening of the second cooling chamber 141 connected to the transport chamber 170 is openable and closable by a gate valve 184. That is to say, the second cooling chamber 141 and the indexer unit 101 are connected to each other through the gate valve 182, and the second cooling chamber 141 and the transport chamber 170 are connected to each other through the gate valve 184.

The gate valve 182 is opened when the semiconductor wafer W is transferred between the indexer unit 101 and the second cooling chamber 141. The gate valve 184 is opened when the semiconductor wafer W is transferred between the second cooling chamber 141 and the transport chamber 170. The inside of the second cooling chamber 141 is an enclosed space when the gate valve 182 and the gate valve 184 are closed.

The transport robot 150 provided in the transport chamber 170 installed adjacent to the chamber 6 can rotate around an axis along the vertical direction as shown by an arrow 150R. The transport robot 150 has two link mechanisms composed of a plurality of arm segments, and a transport hand 151a and a transport hand 151b for holding the semiconductor wafer W are provided at respective leading ends of the two link mechanisms. The transport hand 151a and the transport hand 151b are arranged with a predetermined pitch therebetween in the vertical direction, and are linearly slidably movable in the same horizontal direction independently of each other by the link mechanisms.

The transport robot 150 moves a base on which the two link mechanisms are provided upward and downward to move the transport hand 151a and the transport hand 151b upward and downward while maintaining the predetermined pitch therebetween.

When transferring (taking) the semiconductor wafer W to or from (into or out of) the first cooling chamber 131, the second cooling chamber 141, or the chamber 6 of the thermal processing unit 160, the transport robot 150 first rotates so that both the transport hand 151a and the transport hand 151b oppose the chamber to or from which the semiconductor wafer W is transferred, and, after rotation (or during rotation), moves upward and downward to be located at a level where the semiconductor wafer W is transferred to or from the chamber using one of the transport hands. The transport hand 151a (151b) is then linearly slidably moved in the horizontal direction to transfer the semiconductor wafer W to or from the chamber.

The semiconductor wafer W can be transferred between the transport robot 150 and the transfer robot 120 through the cooling unit 130 and the cooling unit 140. That is to say, the first cooling chamber 131 of the cooling unit 130 and the second cooling chamber 141 of the cooling unit 140 function as paths to transfer the semiconductor wafer W between the transport robot 150 and the transfer robot 120. Specifically, the semiconductor wafer W passed by one of the transport robot 150 and the transfer robot 120 to the first cooling chamber 131 or the second cooling chamber 141 is received by the other one of the transport robot 150 and the transfer robot 120 to transfer the semiconductor wafer W. The transport robot 150 and the transfer robot 120 constitute a transport mechanism for transporting the semiconductor wafer W from the carriers C to the thermal processing unit 160.

As described above, the gate valve 181 is provided between the first cooling chamber 131 and the indexer unit 101, and the gate valve 182 is provided between the second cooling chamber 141 and the indexer unit 101. The gate valve 183 is provided between the transport chamber 170 and the first cooling chamber 131, and the gate valve 184 is provided between the transport chamber 170 and the second cooling chamber 141. Furthermore, a gate valve 185 is provided between the transport chamber 170 and the chamber 6 of the thermal processing unit 160. These gate valves are opened and closed as appropriate when the semiconductor wafer W is transported within the thermal processing apparatus 100.

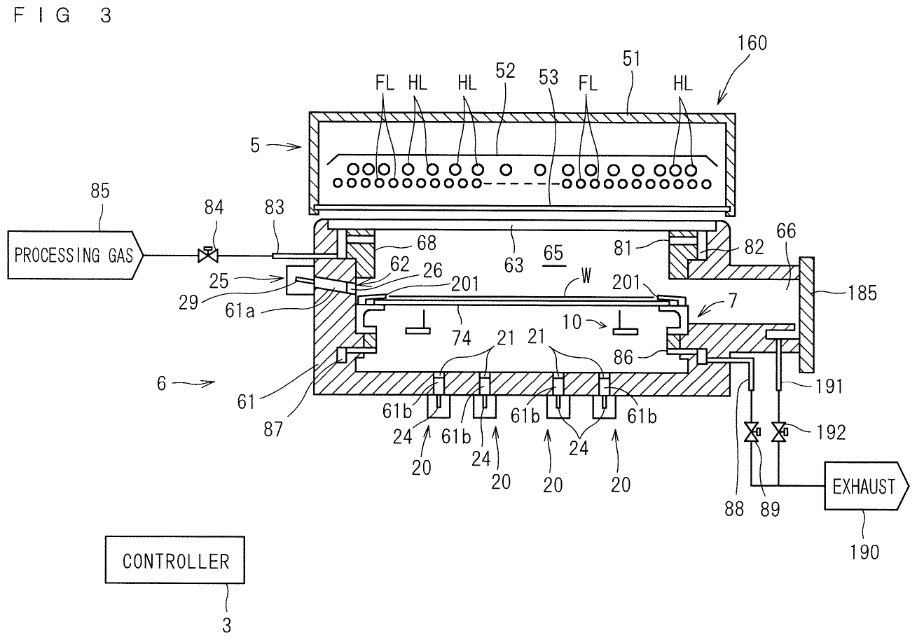

FIG. 3 is a cross-sectional view schematically showing the configuration of the thermal processing unit 160 of the thermal processing apparatus 100 according to the present embodiment.

As illustrated in FIG. 3, the thermal processing unit 160 is a flash lamp annealing apparatus for heating the disk-shaped semiconductor wafer W as the substrate by irradiating the semiconductor wafer W with a flash of light.

The size of the semiconductor wafer W to be processed is not particularly limited, but the semiconductor wafer W has a diameter of 300 mm or 450 mm (300 mm in the present embodiment), for example.

The thermal processing unit 160 includes the chamber 6 for containing the semiconductor wafer W and a heating unit 5 incorporating a plurality of flash lamps FL and a plurality of halogen lamps HL. The heating unit 5 is provided on an upper side of the chamber 6. In an example shown in FIG. 3, the plurality of flash lamps FL are arranged below the plurality of halogen lamps HL. Arrangement, however, is not limited to such arrangement, and the plurality of flash lamps FL and the plurality of halogen lamps HL may be reversely arranged. In plan view, the plurality of flash lamps FL and the plurality of halogen lamps HL may at least partially overlap each other, or may be arranged to avoid the overlap as much as possible. The heating unit 5 includes the plurality of flash lamps FL and the plurality of halogen lamps HL in the present embodiment, but may include arc lamps or light emitting diodes (LEDs) in place of the halogen lamps HL.

The plurality of flash lamps FL heat the semiconductor wafer W by irradiating the semiconductor wafer W with flashes of light. The plurality of halogen lamps HL continuously heat the semiconductor wafer W.

The thermal processing unit 160 also includes, within the chamber 6, a holding unit 7 for holding the semiconductor wafer W in the horizontal position and a transfer mechanism 10 for transferring the semiconductor wafer W between the holding unit 7 and the outside of the apparatus.

The thermal processing unit 160 further includes the controller 3 for controlling each operation mechanism provided in the heating unit 5 and the chamber 6 to perform thermal processing of the semiconductor wafer W.

The chamber 6 includes a chamber housing 61 and an upper chamber window 63 of quartz attached to an upper surface of the chamber housing 61 for blocking.

The upper chamber window 63 forming a ceiling of the chamber 6 is a disk-shaped member including quartz, and functions as a quartz window for transmitting light emitted from the heating unit 5 to the inside of the chamber 6.

A reflective ring 68 is attached to an upper portion of an inner wall surface of the chamber housing 61. The reflective ring 68 is formed to be annular. The reflective ring 68 is attached by being fit to the chamber housing 61 from above. That is to say, the reflective ring 68 is removably attached to the chamber housing 61.

A space inside the chamber 6, that is, a space enclosed by the upper chamber window 63, the chamber housing 61, and the reflective ring 68 is defined as a thermal processing space 65.

By attaching the reflective ring 68 to the chamber housing 61, a recess 62 is formed in the inner wall surface of the chamber 6. The recess 62 is formed in the inner wall surface of the chamber 6 to be annular along the horizontal direction, and surrounds the holding unit 7 for holding the semiconductor wafer W. The chamber housing 61 and the reflective ring 68 each include a metallic material (e.g., stainless steel) having high strength and excellent heat resistance.

The chamber housing 61 has a transport opening (furnace mouth) 66 for transporting the semiconductor wafer W to and from the chamber 6. The transport opening 66 is openable and closable by the gate valve 185. The transport opening 66 is connected in communication with an outer circumferential surface of the recess 62.

The semiconductor wafer W can thus be transported from the transport opening 66 to the thermal processing space 65 through the recess 62, and be transported from the thermal processing space 65 when the gate valve 185 opens the transport opening 66. The thermal processing space 65 in the chamber 6 becomes an enclosed space when the gate valve 185 closes the transport opening 66.

Furthermore, the chamber housing 61 has a through hole 61a and at least one through hole 61b (a plurality of through holes 61b in the present embodiment). The through hole 61a is a cylindrical hole for guiding infrared light radiated from an upper surface of the semiconductor wafer W held by a susceptor 74, which will be described below, to an infrared sensor 29 of an upper radiation thermometer 25. On the other hand, the plurality of through holes 61b are cylindrical holes for guiding infrared light radiated from a lower surface of the semiconductor wafer W to infrared sensors 24 of lower radiation thermometers 20. The through hole 61a is formed in a side portion of the chamber housing 61, and is inclined with respect to the horizontal direction so that an axis thereof in a direction of penetration intersects a main surface of the semiconductor wafer W held by the susceptor 74. On the other hand, the through holes 61b are formed in a bottom portion of the chamber housing 61, and are provided to be substantially perpendicular to the horizontal direction so that axes thereof in a direction of penetration are substantially orthogonal to the main surface of the semiconductor wafer W held by the susceptor 74. The through holes 61b may not have the axes in the direction of penetration substantially orthogonal to the main surface of the semiconductor wafer W, and may be inclined with respect to the horizontal direction so that the axes intersect the main surface of the semiconductor wafer W.

The infrared sensor 29 and at least one infrared sensor 24 (the plurality of infrared sensors 24 in the present embodiment) are each a pyroelectric sensor utilizing a pyroelectric effect, a thermopile utilizing the Seebeck effect, a thermal infrared sensor, such as a bolometer, utilizing a change in resistance of a semiconductor by heat, or a quantum infrared sensor, for example.

A wavelength region measurable by the infrared sensor 29 is 5 μm or more and 6.5 μm or less, for example. On the other hand, a wavelength region measurable by each of the infrared sensors 24 is 0.2 μm or more and 3 μm or less, preferably 0.9 μm or less, for example.

The infrared sensor 29 has an optical axis inclined with respect to the main surface of the semiconductor wafer W held by the susceptor 74, and receives the infrared light radiated from the upper surface of the semiconductor wafer W. On the other hand, the infrared sensors 24 arranged on a lower side of the semiconductor wafer W have optical axes substantially orthogonal to the main surface of the semiconductor wafer W held by the susceptor 74, and receive the infrared light radiated from the lower surface of the semiconductor wafer W.

A transparent window 26 including a calcium fluoride material transmitting infrared light in a wavelength region measurable by the upper radiation thermometer 25 is attached to an end of the through hole 61a facing the thermal processing space 65. Transparent windows 21 including a barium fluoride material transmitting infrared light in a wavelength region measurable by the lower radiation thermometers 20 are attached to ends of the through holes 61b facing the thermal processing space 65. The transparent windows 21 may include quartz, for example.

A gas supply hole 81 for supplying processing gas to the thermal processing space 65 is formed in an upper portion of an inner wall of the chamber 6. The gas supply hole 81 is formed at a location on an upper side of the recess 62, and may be provided in the reflective ring 68. The gas supply hole 81 is connected in communication with a gas supply tube 83 through a buffer space 82 formed to be annular inside a side wall of the chamber 6.

The gas supply tube 83 is connected to a processing gas supply source 85. A valve 84 is inserted along a path of the gas supply tube 83. When the valve 84 is opened, the processing gas is supplied from the processing gas supply source 85 to the buffer space 82.

The processing gas having flowed in the buffer space 82 flows throughout the buffer space 82 having a lower fluid resistance than the gas supply hole 81, and is supplied to the thermal processing space 65 through the gas supply hole 81. As the processing gas, inert gas, such as nitrogen (N₂), reactive gas, such as hydrogen (H₂) and ammonia (NH₃), or mixed gas as a mixture of them can be used (nitrogen gas in the present embodiment).

On the other hand, a gas exhaust hole 86 for exhausting gas within the thermal processing space 65 is formed in a lower portion of the inner wall of the chamber 6. The gas exhaust hole 86 is connected in communication with a gas exhaust tube 88 through a buffer space 87 formed to be annular inside the side wall of the chamber 6. The gas exhaust tube 88 is connected to an exhaust unit 190. A valve 89 is inserted along a path of the gas exhaust tube 88. When the valve 89 is opened, gas within the thermal processing space 65 is exhausted from the gas exhaust hole 86 to the gas exhaust tube 88 through the buffer space 87.

The gas supply hole 81 and the gas exhaust hole 86 may each include a plurality of holes arranged along the circumference of the chamber 6, or may each be a slit. The processing gas supply source 85 and the exhaust unit 190 may each be a mechanism provided in the thermal processing unit 160, and may each be a utility of a plant in which the thermal processing unit 160 is installed.

A gas exhaust tube 191 for exhausting gas within the thermal processing space 65 is also connected to a leading end of the transport opening 66. The gas exhaust tube 191 is connected to the exhaust unit 190 through a valve 192. Gas within the chamber 6 is exhausted through the transport opening 66 by opening the valve 192.

A light blocking member 201 is disposed above the holding unit 7 within the chamber 6. The light blocking member 201 is disposed to surround the semiconductor wafer W held by the susceptor 74 in plan view. The light blocking member 201 is disposed to be contiguous with an outer edge of the semiconductor wafer W in plan view, so that a region above the semiconductor wafer W and a region below the semiconductor wafer W are separated to block light directed from the heating unit 5 toward the region below the semiconductor wafer W. The light blocking member 201 may be disposed below the holding unit 7.

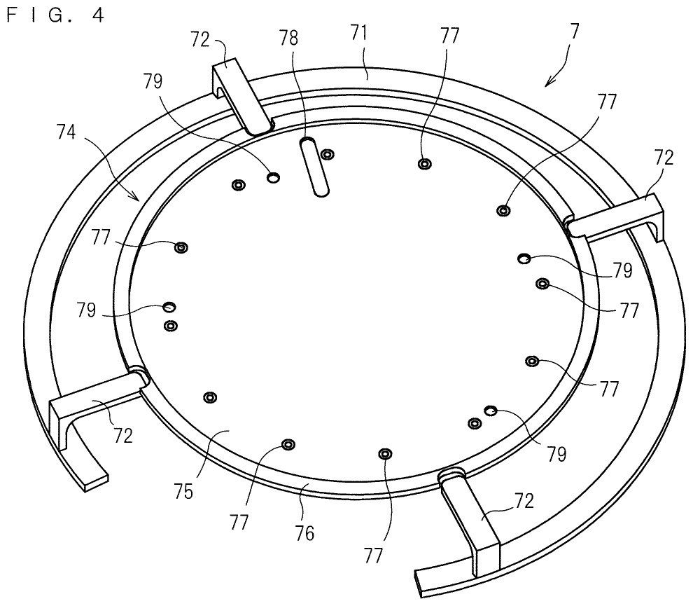

FIG. 4 is a perspective view illustrating appearance of the holding unit 7 as a whole. The holding unit 7 includes a base ring 71, connectors 72, and the susceptor 74. The base ring 71, the connectors 72, and the susceptor 74 each include quartz. That is to say, the holding unit 7 as a whole includes quartz.

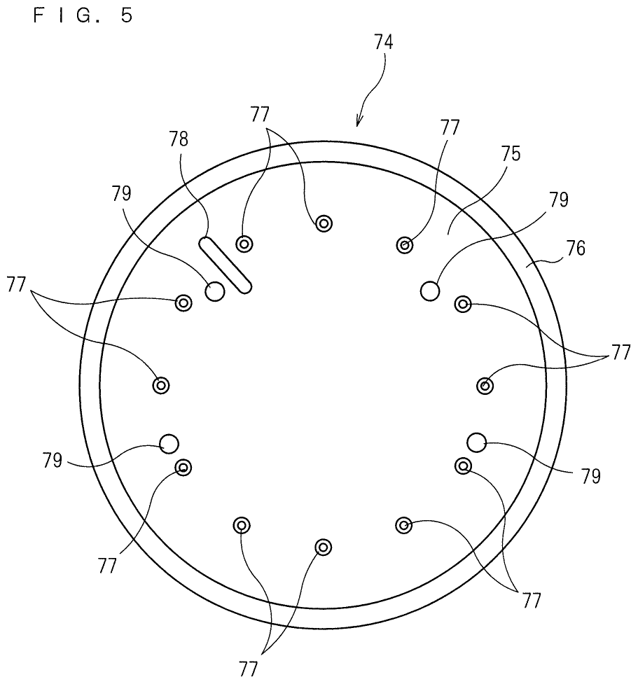

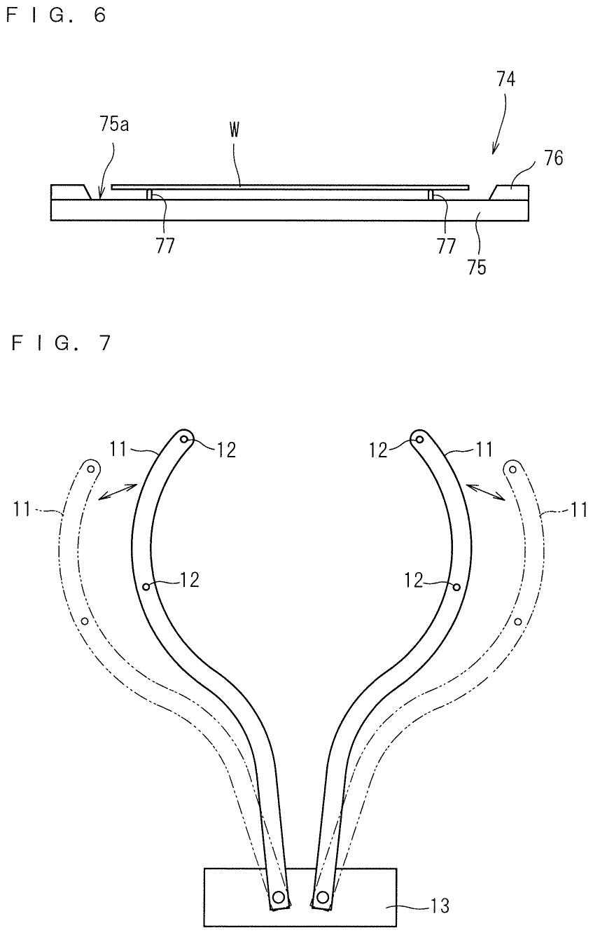

The base ring 71 is a quartz member having an arc shape that is a partially-missing annular shape. The missing portion is provided to prevent interference between transfer arms 11 of the transfer mechanism 10, which will be described below, and the base ring 71. The base ring 71 is mounted on a bottom surface of the recess 62 to be supported by a wall surface of the chamber 6 (see FIG. 3). The plurality of connectors 72 (four connectors 72 in the present embodiment) are provided to stand on an upper surface of the base ring 71 along the circumference of the annular shape thereof. The connectors 72 are also quartz members, and are fixed to the base ring 71 by welding. The susceptor 74 is supported by the four connectors 72 provided on the base ring 71 from below. FIG. 5 is a plan view of the susceptor 74. FIG. 6 is a cross-sectional view of the susceptor 74.

The susceptor 74 includes a holding plate 75, a guide ring 76, and a plurality of support pins 77. The holding plate 75 is a substantially circular planar member including quartz. The holding plate 75 has a greater diameter than the semiconductor wafer W. That is to say, the holding plate 75 has a greater planar size than the semiconductor wafer W.

The guide ring 76 is provided at a periphery on an upper surface of the holding plate 75. The guide ring 76 is an annular member having an inner diameter greater than the diameter of the semiconductor wafer W. For example, the guide ring 76 has an inner diameter of 320 mm in a case where the semiconductor wafer W has a diameter of 300 mm.

An inner circumference of the guide ring 76 is a tapered surface widening upward from the holding plate 75. The guide ring 76 includes quartz as with the holding plate 75.

The guide ring 76 may be welded onto the upper surface of the holding plate 75 or may be fixed to the holding plate 75 with pins and the like processed separately. Alternatively, the holding plate 75 and the guide ring 76 may be processed as an integral member.

A region of the upper surface of the holding plate 75 inside the guide ring 76 is a planar holding surface 75a for holding the semiconductor wafer W. The plurality of support pins 77 are provided on the holding surface 75a of the holding plate 75. In the present embodiment, a total of 12 support pins 77 are annularly provided at 30° intervals to stand on a circumference of a circle concentric with an outer circumference of the holding surface 75a (the inner circumference of the guide ring 76).

The diameter of the circle on which the 12 support pins 77 are arranged (the distance between opposite support pins 77) is smaller than the diameter of the semiconductor wafer W, and is 210 mm to 280 mm if the semiconductor wafer W has a diameter of 300 mm. The number of support pins 77 is three or more. The support pins 77 each include quartz.

The plurality of support pins 77 may be provided on the upper surface of the holding plate 75 by welding, or may processed to be integral with the holding plate 75.

Referring back to FIG. 4, the four connectors 72 provided to stand on the base ring 71 and the periphery of the holding plate 75 of the susceptor 74 are fixed to each other by welding. That is to say, the susceptor 74 and the base ring 71 are fixedly connected to each other by the connectors 72. The base ring 71 of the holding unit 7 as described above is supported by the wall surface of the chamber 6, so that the holding unit 7 is attached to the chamber 6. When the holding unit 7 is in a state of being attached to the chamber 6, the holding plate 75 of the susceptor 74 is in the horizontal position (in a position in which a normal thereto is coincident with the vertical direction). That is to say, the holding surface 75a of the holding plate 75 is a horizontal surface.

The semiconductor wafer W transported to the chamber 6 is mounted on the susceptor 74 of the holding unit 7 attached to the chamber 6, and is held in the horizontal position. In this case, the semiconductor wafer W is supported by the 12 support pins 77 provided to stand on the holding plate 75 to be supported by the susceptor 74 from below. More strictly, upper ends of the 12 support pins 77 are in contact with the lower surface of the semiconductor wafer W to support the semiconductor wafer W.

The 12 support pins 77 have a uniform height (the distance from the upper ends of the support pins 77 to the holding surface 75a of the holding plate 75), and thus can support the semiconductor wafer W in the horizontal position.

The semiconductor wafer W is supported by the plurality of support pins 77 to be spaced apart from the holding surface 75a of the holding plate 75 by a predetermined distance. The thickness of the guide ring 76 is greater than the height of each of the support pins 77. Misalignment in the horizontal direction of the semiconductor wafer W supported by the plurality of support pins 77 is thus prevented by the guide ring 76.

As illustrated in FIGS. 4 and 5, the holding plate 75 of the susceptor 74 has an opening 78 vertically passing through the holding plate 75. The opening 78 is provided for the lower radiation thermometers 20 to receive light (infrared light) radiated from the lower surface of the semiconductor wafer W. That is to say, the lower radiation thermometers 20 measure the temperature of the semiconductor wafer W by receiving light radiated from the lower surface of the semiconductor wafer W through the opening 78 and the transparent windows 21 attached to the through holes 61b of the chamber housing 61.

The holding plate 75 of the susceptor 74 further has four through holes 79 through which lift pins 12 of the transfer mechanism 10, which will be described below, are to penetrate for a transfer of the semiconductor wafer W.

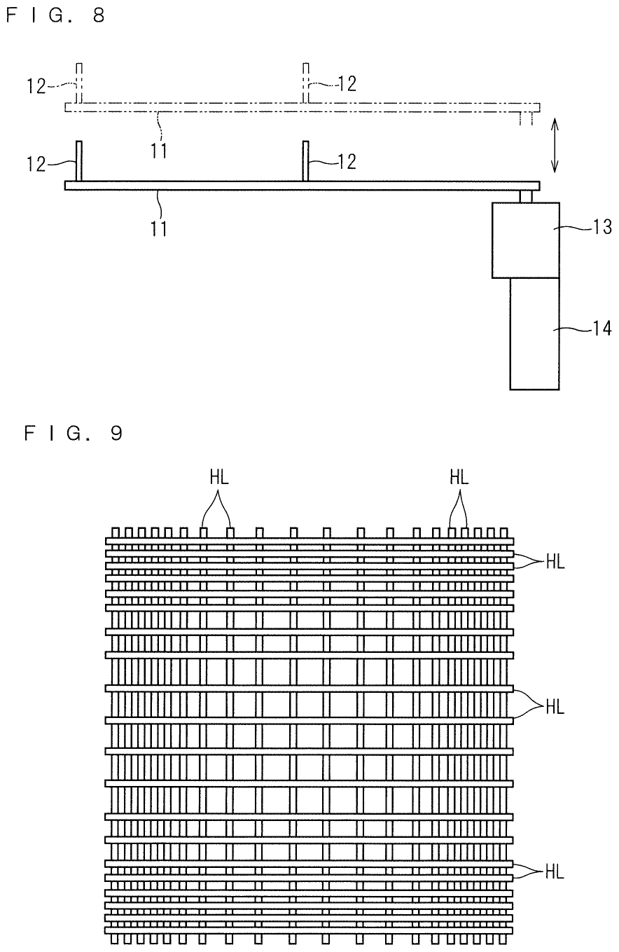

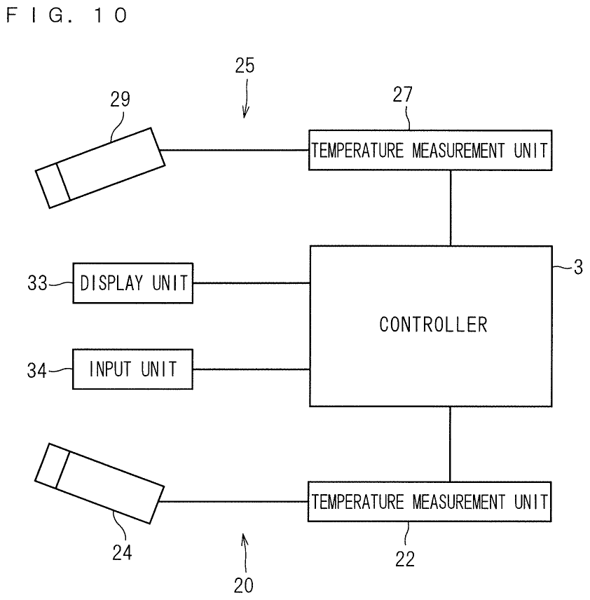

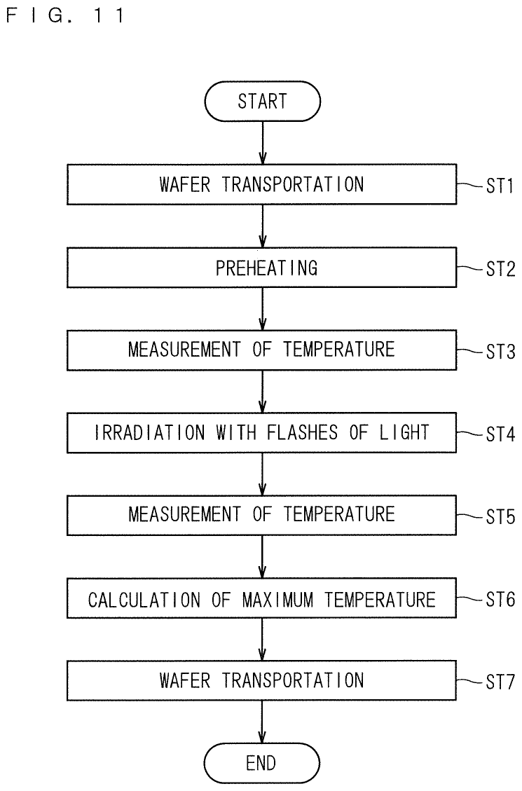

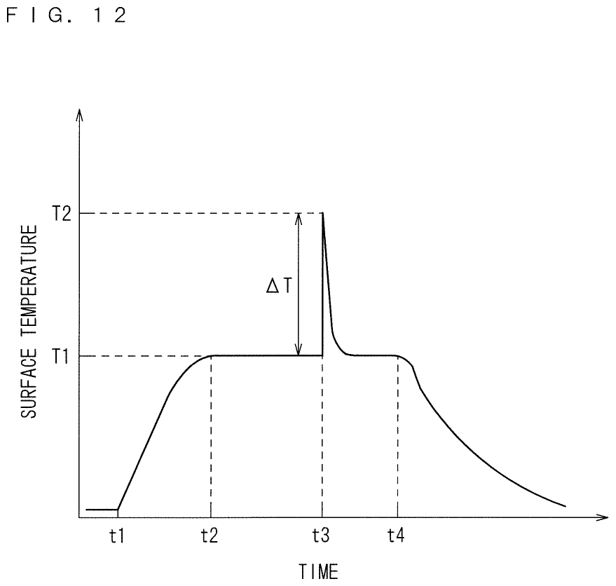

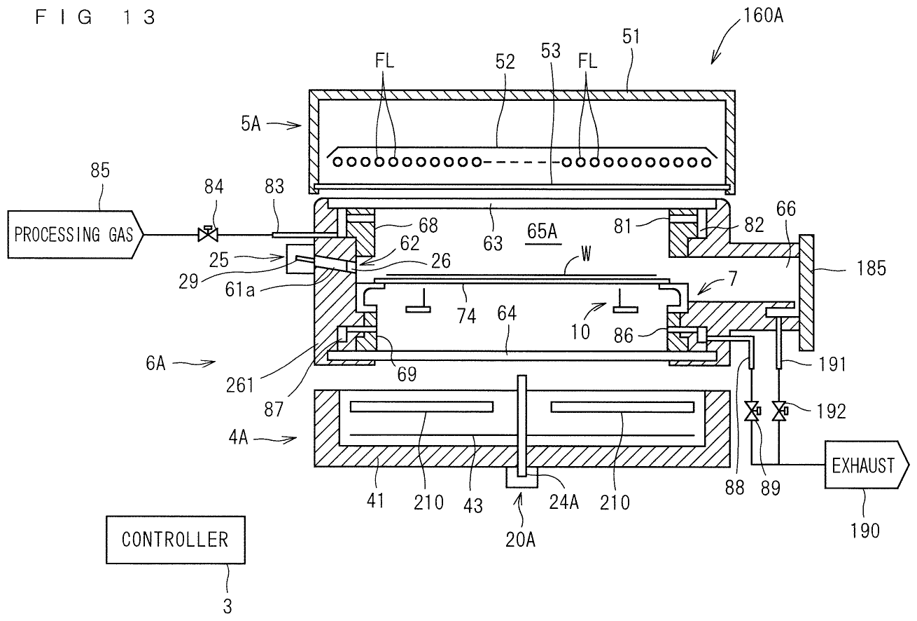

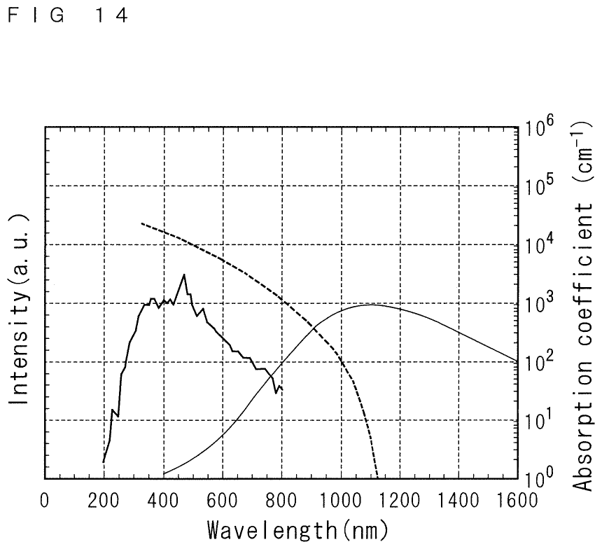

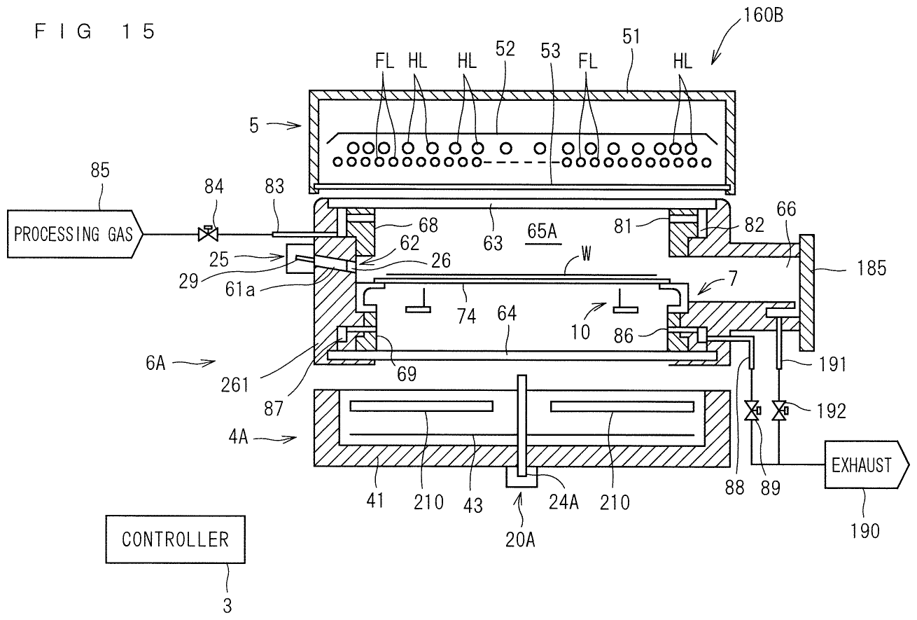

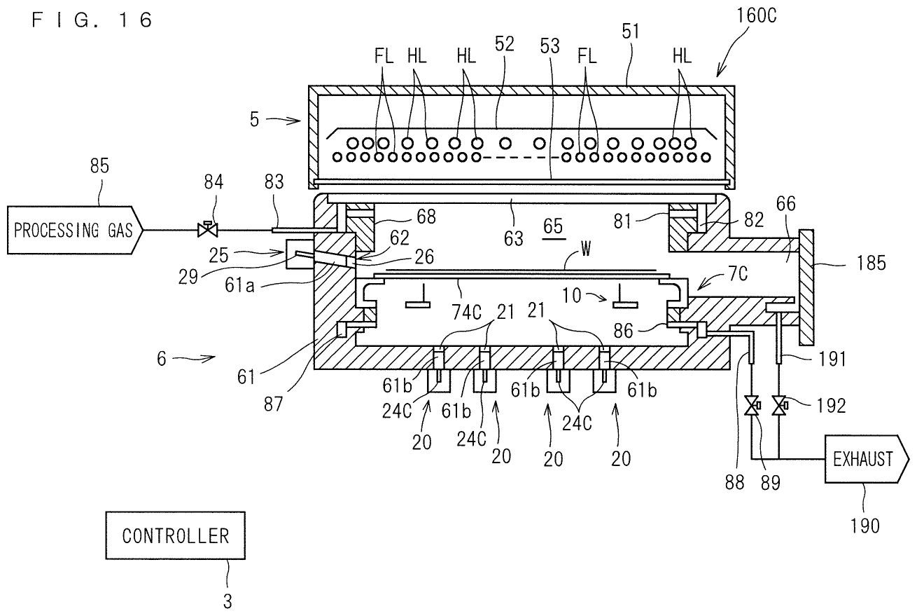

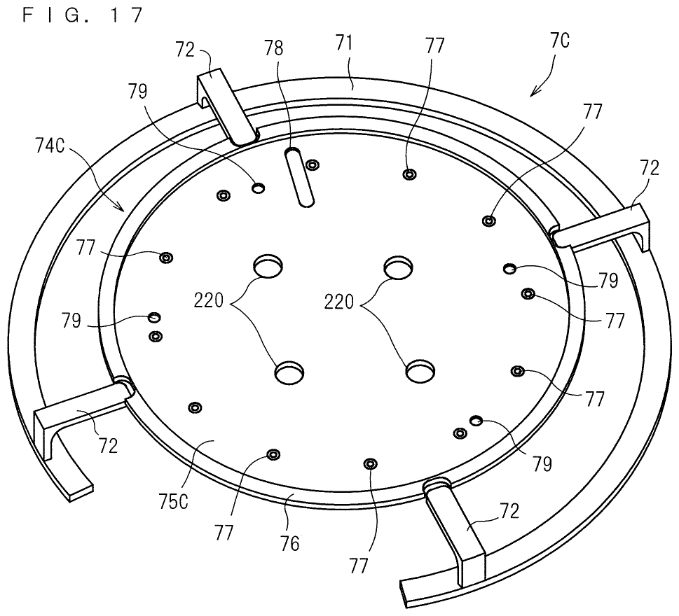

FIG. 7 is a plan view of the transfer mechanism 10. FIG. 8 is a side view of the transfer mechanism 10. The transfer mechanism 10 includes two transfer arms 11. The transfer arms 11 have an arc shape substantially along the recess 62 formed to be annular.

Two lift pins 12 are provided to stand on each of the transfer arms 11. The transfer arms 11 and the lift pins 12 each include quartz. The transfer arms 11 are each pivotable by a horizontal movement mechanism 13. The horizontal movement mechanism 13 horizontally moves the pair of transfer arms 11 between a transfer operation location (a location in solid lines in FIG. 7) where the semiconductor wafer W is transferred to and from the holding unit 7 and a withdrawal location (a location in alternate long and two short dashes lines in FIG. 7) where the pair of transfer arms 11 does not overlap the semiconductor wafer W held by the holding unit 7 in plan view.

The horizontal movement mechanism 13 may pivot the transfer arms 11 by separate motors, or may pivot the transfer arms 11 in conjunction with each other by a single motor using a link mechanism.

The pair of transfer arms 11 is moved upward and downward by a lift mechanism 14 along with the horizontal movement mechanism 13. When the lift mechanism 14 moves the pair of transfer arms 11 upward at the transfer operation location, a total of four lift pins 12 pass through the through holes 79 (see FIGS. 4 and 5) formed in the susceptor 74, and upper ends of the lift pins 12 protrude from the upper surface of the susceptor 74. On the other hand, when the lift mechanism 14 moves the pair of transfer arms 11 downward at the transfer operation location to draw the lift pins 12 from the through holes 79, and the horizontal movement mechanism 13 moves the pair of transfer arms 11 to open the transfer arms 11, the transfer arms 11 are moved to the withdrawal location.

The withdrawal location of the pair of transfer arms 11 is immediately above the base ring 71 of the holding unit 7. The base ring 71 is mounted on the bottom surface of the recess 62, so that the withdrawal location of the transfer arms 11 is inside the recess 62. An exhaust mechanism, which is not illustrated, is provided near a location where a drive unit (the horizontal movement mechanism 13 and the lift mechanism 14) of the transfer mechanism 10 is provided to exhaust an atmosphere around the drive unit of the transfer mechanism 10 to the outside of the chamber 6.

Referring back to FIG. 3, the heating unit 5 provided above the chamber 6 includes, within a housing 51, a light source composed of the plurality of flash lamps FL (30 flash lamps FL in the present embodiment) and a reflector 52 provided to cover the light source from above.

A lamp light radiation window 53 is attached to the bottom of the housing 51 of the heating unit 5. The lamp light radiation window 53 forming a floor of the heating unit 5 is a plate-like quartz window including quartz. The heating unit 5 is installed above the chamber 6, so that the lamp light radiation window 53 opposes the upper chamber window 63.

The flash lamps FL irradiate the thermal processing space 65 with flashes of light from above the chamber 6 through the lamp light radiation window 53 and the upper chamber window 63.

The plurality of flash lamps FL are each a rod-like lamp having an elongated cylindrical shape, and are in planar arrangement so that longitudinal directions thereof are parallel to one another along the main surface of the semiconductor wafer W held by the holding unit 7 (i.e., along the horizontal direction). A plane formed by arrangement of the flash lamps FL is thus a horizontal plane.

Each of the flash lamps FL includes a rod-like glass tube (discharge tube) in which xenon gas is enclosed and which has, at opposite ends thereof, an anode and a cathode connected to a capacitor, and a trigger electrode attached to an outer circumferential surface of the glass tube.

Xenon gas is electrically an insulator, so that electricity does not flow through the glass tube in a normal state even if electric charge is accumulated in the capacitor. In a case where a high voltage is applied to the trigger electrode to cause electrical breakdown, however, electricity stored in the capacitor instantaneously flows through the glass tube, and light is emitted by excitation of atoms or molecules of xenon at the time.

In such a flash lamp FL, electrostatic energy stored in advance in the capacitor is converted into an extremely short light pulse of 0.1 ms to 100 ms. The flash lamp FL thus has a feature of being capable of emitting extremely intense light compared with a continuous illumination light source, such as a halogen lamp HL. That is to say, the flash lamp FL is a pulsed light emitting lamp momentarily emitting light in an extremely short time of less than one second.

A light emitting time of the flash lamp FL can be adjusted by a coil constant of a lamp power supply for supplying power to the flash lamp FL.

The reflector 52 is provided above the plurality of flash lamps FL to cover the flash lamps FL as a whole. A basic function of the reflector 52 is to reflect flashes of light emitted from the plurality of flash lamps FL toward the thermal processing space 65. The reflector 52 is formed of an aluminum alloy plate, and has an upper surface (a surface facing the flash lamps FL) having been roughened by blasting.

The heating unit 5 provided above the chamber 6 incorporates the plurality of halogen lamps HL (40 halogen lamps HL in the present embodiment) in the housing 51. The heating unit 5 heats the semiconductor wafer W by irradiating the thermal processing space 65 with light from above the chamber 6 through the upper chamber window 63 using the plurality of halogen lamps HL.

FIG. 9 is a plan view illustrating arrangement of the plurality of halogen lamps HL of the heating unit 5. The 40 halogen lamps HL are arranged separately in two tiers. In a lower tier closer to the holding unit 7, 20 halogen lamps HL are arranged, and, in an upper tier farther from the holding unit 7 than the lower tier is, 20 halogen lamps HL are arranged.

The halogen lamps HL are each a rod-like lamp having an elongated cylindrical shape. The 20 halogen lamps HL in each of the upper and lower tiers are arranged so that longitudinal directions thereof are parallel to one another along the main surface of the semiconductor wafer W held by the holding unit 7 (i.e., along the horizontal direction). A plane formed by arrangement of the halogen lamps HL in each of the upper and lower tiers is thus a horizontal plane.

As illustrated in FIG. 9, the halogen lamps HL arranged in each of the upper and lower tiers are denser in a region opposing the periphery of the semiconductor wafer W held by the holding unit 7 than in a region opposing a central portion of the semiconductor wafer W held by the holding unit 7. That is to say, the halogen lamps HL arranged in each of the upper and lower tiers have a shorter pitch at the periphery than in a central portion of arrangement of the lamps. The periphery of the semiconductor wafer W where reduction in temperature is more likely to occur at heating due to light irradiation by the heating unit 5 can thus be irradiated with a greater amount of light.

The halogen lamps HL are arranged so that the halogen lamps HL in the upper tier and the halogen lamps HL in the lower tier intersect each other in a grid. That is to say, a total of 40 halogen lamps HL are arranged so that longitudinal directions of the 20 halogen lamps HL arranged in the upper tier and longitudinal directions of the 20 halogen lamps HL arranged in the lower tier are orthogonal to each other.

Each of the halogen lamps HL is a filament light source causing a filament disposed inside a glass tube to glow by allowing a current to pass therethrough to thereby emit light. Gas obtained by introducing traces of halogen elements (e.g., iodide and bromine) into inert gas, such as nitrogen and argon, is enclosed in the glass tube. Introduction of halogen elements allows for setting the temperature of the filament to a high temperature while suppressing breakage of the filament.

The halogen lamp HL thus has properties of having a longer life and being capable of continuously emitting intense light compared with a typical incandescent lamp. That is to say, the halogen lamp HL is a continuous illumination lamp continuously emitting light for at least one second or more. The halogen lamps HL have long lives as they are rod-like lamps, and have excellent radiation efficiency toward the semiconductor wafer W below the halogen lamps HL by being arranged along the horizontal direction.

As illustrated in FIG. 3, two types of radiation thermometers (pyrometers in the present embodiment), namely, the upper radiation thermometer 25 and the lower radiation thermometers 20, are provided to the chamber 6. The upper radiation thermometer 25 is provided obliquely above the semiconductor wafer W held by the susceptor 74, and the lower radiation thermometers 20 are provided below the semiconductor wafer W held by the susceptor 74.

FIG. 10 shows the relationship among each of the lower radiation thermometers 20, the upper radiation thermometer 25, and the controller 3.

The lower radiation thermometers 20 provided below the semiconductor wafer W to measure the temperature on the lower surface of the semiconductor wafer W each include an infrared sensor 24 and a temperature measurement unit 22.

The infrared sensor 24 receives the infrared light radiated from the lower surface of the semiconductor wafer W held by the susceptor 74 through the opening 78. The infrared sensor 24 is electrically connected to the temperature measurement unit 22, and transmits a signal generated in response to reception of the light to the temperature measurement unit 22.

The temperature measurement unit 22 includes an amplifying circuit, an A/D convertor, a temperature conversion circuit, and the like, which are not illustrated, and converts the signal indicating intensity of the infrared light output from the infrared sensor 24 into the temperature. The temperature acquired by the temperature measurement unit 22 is the temperature on the lower surface of the semiconductor wafer W.

On the other hand, the upper radiation thermometer 25 provided obliquely above the semiconductor wafer W to measure the temperature on the upper surface of the semiconductor wafer W includes the infrared sensor 29 and a temperature measurement unit 27. The infrared sensor 29 receives the infrared light radiated from the upper surface of the semiconductor wafer W held by the susceptor 74. The infrared sensor 29 includes an optical device including InSb (indium antimonide) to respond to a rapid change in temperature on the upper surface of the semiconductor wafer W at the moment when the upper surface is irradiated with a flash of light. The infrared sensor 29 is electrically connected to the temperature measurement unit 27, and transmits a signal generated in response to reception of the light to the temperature measurement unit 27.

The temperature measurement unit 27 converts the signal indicating intensity of the infrared light output from the infrared sensor 29 into the temperature. The temperature acquired by the temperature measurement unit 27 is the temperature on the upper surface of the semiconductor wafer W.

The lower radiation thermometers 20 and the upper radiation thermometer 25 are electrically connected to the controller 3 as a controller for the thermal processing unit 160 as a whole, and the temperature on the lower surface of the semiconductor wafer W measured by the lower radiation thermometers 20 and the temperature on the upper surface of the semiconductor wafer W measured by the upper radiation thermometer 25 are transmitted to the controller 3.

The controller 3 controls the above-mentioned various operation mechanisms provided in the thermal processing unit 160. The controller 3 has a similar hardware configuration to a typical computer. That is to say, the controller 3 includes a CPU as a circuit for performing various types of arithmetic processing, ROM as read-only memory for storing a basic program, RAM as read/write memory for storing various pieces of information, and a magnetic disk for storing control software, data, and the like. The CPU of the controller 3 executes a predetermined processing program to proceed with processing performed by the thermal processing unit 160.

A display unit 33 and an input unit 34 are connected to the controller 3. The controller 3 causes the display unit 33 to display various pieces of information. The input unit 34 is equipment for an operator of the thermal processing apparatus 100 to input various commands or parameters to the controller 3. The operator can set, through the input unit 34, conditions for a processing recipe in which procedures of and conditions for processing of the semiconductor wafer W are described while checking display content of the display unit 33.

As the display unit 33 and the input unit 34, a touch panel having functions of both of them can be used, and a liquid crystal touch panel provided on an outer wall of the thermal processing apparatus 100 is used in the present embodiment.

In addition to the above-mentioned components, the thermal processing apparatus 100 includes various structures for cooling to prevent an excessive temperature rise of the heating unit 5 and the chamber 6 caused by thermal energy generated by the halogen lamps HL and the flash lamps FL at thermal processing of the semiconductor wafer W.

For example, a water-cooled tube (not illustrated) is provided in a wall body of the chamber 6. The heating unit 5 has an air-cooled structure in which a gas flow is formed to exhaust heat. Air is supplied to a gap between the upper chamber window 63 and the lamp light radiation window 53 to cool the heating unit 5 and the upper chamber window 63.

<Operation of Thermal Processing Apparatus>

Procedures of processing of the semiconductor wafer W performed by the thermal processing apparatus 100 will be described next. FIG. 11 is a flowchart showing the procedures of processing of the semiconductor wafer W. The controller 3 controls each of the operation mechanisms of the thermal processing apparatus 100 to proceed with the procedures of processing performed by the thermal processing apparatus 100 described below.

First, the valve 84 for supplying gas is opened, and the valve 89 and the valve 192 for exhausting gas are opened to start supply and exhaust of gas to and from the chamber 6. When the valve 84 is opened, nitrogen gas is supplied through the gas supply hole 81 to the thermal processing space 65. When the valve 89 is opened, gas in the chamber 6 is exhausted from the gas exhaust hole 86. The nitrogen gas supplied from an upper portion of the thermal processing space 65 in the chamber 6 thereby flows downward, and is exhausted from a lower portion of the thermal processing space 65.

Gas in the chamber 6 is also exhausted from the transport opening 66 by opening the valve 192. Furthermore, the atmosphere around the drive unit of the transfer mechanism 10 is exhausted by the exhaust mechanism, which is not illustrated. When the thermal processing apparatus 100 performs thermal processing on the semiconductor wafer W, the nitrogen gas is continuously supplied to the thermal processing space 65, and the amount of supply is changed as appropriate in accordance with a step of processing.

Then, the gate valve 185 is opened to open the transport opening 66, and the transport robot outside the apparatus transports the semiconductor wafer W to be processed to the thermal processing space 65 in the chamber 6 through the transport opening 66 (step ST1). In this case, an atmosphere outside the apparatus can be entrained by transportation of the semiconductor wafer W, but, since the nitrogen gas is continued to be supplied to the chamber 6, the nitrogen gas flows out from the transport opening 66 to minimize such entrainment of the atmosphere outside the apparatus.

The semiconductor wafer W transported by the transport robot is moved to a location immediately above the holding unit 7, and is stopped. The pair of transfer arms 11 of the transfer mechanism 10 horizontally moves from the withdrawal location to the transfer operation location, and moves upward, so that the lift pins 12 pass through the through holes 79 to protrude from the upper surface of the holding plate 75 of the susceptor 74, and receive the semiconductor wafer W. In this case, the lift pins 12 are moved above the upper ends of the support pins 77.

After the semiconductor wafer W is mounted on the lift pins 12, the transport robot leaves the thermal processing space 65, and the transport opening 66 is closed by the gate valve 185. The pair of transfer arms 11 moves downward, so that the semiconductor wafer W is transferred from the transfer mechanism 10 to the susceptor 74 of the holding unit 7, and is held in the horizontal position from below. The semiconductor wafer W is held by the susceptor 74 by being supported by the plurality of support pins 77 provided to stand on the holding plate 75. The semiconductor wafer W is held by the holding unit 7 with an objective surface facing upward. There is a predetermined distance between the lower surface (a main surface opposite the upper surface) of the semiconductor wafer W supported by the plurality of support pins 77 and the holding surface 75a of the holding plate 75. The pair of transfer arms 11 having moved downward to a location below the susceptor 74 is withdrawn by the horizontal movement mechanism 13 to the withdrawal location, that is, to the inside of the recess 62.

FIG. 12 shows a change in temperature on the upper surface of the semiconductor wafer W. After the semiconductor wafer W is transported to the chamber 6 and held by the susceptor 74, the 40 halogen lamps HL of the heating unit 5 are simultaneously turned on at time t1 to start preheating (assist heating) (step ST2). Halogen light emitted from the halogen lamps HL is transmitted through the lamp light radiation window 53 and the upper chamber window 63 each including quartz, and is applied to the upper surface of the semiconductor wafer W. By being irradiated with light from the halogen lamps HL, the semiconductor wafer W is preheated to have a raised temperature. The transfer arms 11 of the transfer mechanism 10 are withdrawn to the inside of the recess 62, and thus do not interfere with heating by the halogen lamps HL.

The temperature of the semiconductor wafer W raised by irradiation with light from the halogen lamps HL is measured by the upper radiation thermometer 25 or the lower radiation thermometers 20 (step ST3). The upper radiation thermometer 25 or the lower radiation thermometers 20 may start measuring the temperature before the start of preheating by the halogen lamps HL.

When the temperature of the semiconductor wafer W is contactlessly measured by the upper radiation thermometer 25 or the lower radiation thermometers 20, emissivity of the semiconductor wafer W is required to be set to the radiation thermometer to be used for measurement. If no film is formed on the main surface of the semiconductor wafer W, emissivity of silicon as a base material for the wafer should be set to the radiation thermometer. If any film is formed on the main surface of the semiconductor wafer W, however, emissivity varies with the film.

The wavelength region measurable by each of the infrared sensors 24 of the lower radiation thermometers 20 is 0.2 μm or more and 3 μm or less, preferably 0.9 μm or less, for example, and thus at least partially overlaps a wavelength region of light emitted from the halogen lamps HL (e.g., 0.8 μm or more and 2 μm or less).

Since the light blocking member 201 is provided above the holding unit 7, in a region not overlapping the semiconductor wafer W in plan view, light emitted from the halogen lamps HL is blocked by the light blocking member 201, and little light reaches a location below the holding unit 7. In a region overlapping the semiconductor wafer W in plan view, light at a wavelength in the wavelength region measurable by each of the infrared sensors 24 is sufficiently absorbed by the semiconductor wafer W, and little light reaches the location below the holding unit 7. Direct reception of the light emitted from the halogen lamps HL by each of the infrared sensors 24 is thereby sufficiently suppressed.

In order for each of the infrared sensors 24 to receive the infrared light radiated from the lower surface of the semiconductor wafer W, the light is required to be transmitted through the holding plate 75 located below the semiconductor wafer W. Since the wavelength region measurable by each of the infrared sensors 24 is 0.2 μm or more and 3 μm or less, preferably 0.9 μm or less, for example, in the present embodiment, each of the infrared sensors 24 can measure light in a wavelength region capable of sufficiently being transmitted through the holding plate 75 consisting of quartz.

The temperature of the semiconductor wafer W measured by the upper radiation thermometer 25 or the lower radiation thermometers 20 is transmitted to the controller 3. The controller 3 controls output of the halogen lamps HL while monitoring the temperature of the semiconductor wafer W raised by irradiation with light from the halogen lamps HL to determine whether it has reached a predetermined preheat temperature T1. That is to say, the controller 3 performs feedback control of output of the halogen lamps HL based on a value measured by the upper radiation thermometer 25 or the lower radiation thermometers 20 so that the temperature of the semiconductor wafer W becomes the preheat temperature T1. The preheat temperature T1 is, for example, 200° C. or more and 800° C. or less at which there is no possibility of diffusion of the impurities added to the semiconductor wafer W due to heat, and is preferably 350° C. or more and 600° C. or less (600° C. in the present embodiment).

After the temperature of the semiconductor wafer W has reached the preheat temperature T1, the controller 3 maintains the semiconductor wafer W at the preheat temperature T1 for a while. Specifically, at time t2 when the temperature of the semiconductor wafer W measured by the upper radiation thermometer 25 or the lower radiation thermometers 20 has reached the preheat temperature T1, the controller 3 adjusts output of the halogen lamps HL to maintain the semiconductor wafer W substantially at the preheat temperature T1.

The temperature of the semiconductor wafer W as a whole is uniformly raised to the preheat temperature T1 through preheating by the halogen lamps HL as described above. At the stage of preheating by the halogen lamps HL, the temperature at the periphery of the semiconductor wafer W where heat is more likely to be dissipated tends to be lower than the temperature in the central portion of the semiconductor wafer W, but the halogen lamps HL of the heating unit 5 are denser in the region opposing the periphery than in the region opposing the central portion of the semiconductor wafer W. The periphery of the semiconductor wafer W where heat is more likely to be dissipated is thus irradiated with a greater amount of light to make in-plane temperature distribution of the semiconductor wafer W uniform at the preheating stage.

At time t3 when a predetermined time has elapsed since reaching of the temperature of the semiconductor wafer W to the preheat temperature T1, the flash lamps FL of the heating unit 5 irradiate the upper surface of the semiconductor wafer W held by the susceptor 74 with flashes of light (step ST4). In this case, some flashes of light radiated from the flash lamps FL are directly directed toward the inside of the chamber 6, and the other flashes of light radiated from the flash lamps FL are once reflected by the reflector 52 and then directed toward the inside of the chamber 6, so that the semiconductor wafer W is flash heated by irradiation with these flashes of light.

The semiconductor wafer W is flash heated through irradiation with flashes of light from the flash lamps FL, and thus the temperature on the upper surface of the semiconductor wafer W can be raised in a short time. That is to say, flashes of light emitted from the flash lamps FL are intense flashes of light having an extremely short irradiation time of approximately 0.1 ms or more and 100 ms or less obtained by converting electrostatic energy stored in advance in the capacitor into an extremely short light pulse. The temperature on the upper surface of the semiconductor wafer W is rapidly raised in an extremely short time through irradiation with flashes of light from the flash lamps FL.

The temperature of the semiconductor wafer W is monitored by the upper radiation thermometer 25 or the lower radiation thermometers 20. The upper radiation thermometer 25 herein does not measure an absolute temperature on the upper surface of the semiconductor wafer W but measures a change in temperature on the upper surface (step ST5). That is to say, the upper radiation thermometer 25 measures a raised temperature (jump temperature) ΔT by which the temperature on the upper surface of the semiconductor wafer W is raised from the preheat temperature T1 at irradiation with flashes of light. Although the temperature on the lower surface of the semiconductor wafer W is also measured by the lower radiation thermometers 20 at irradiation with flashes of light, only a portion near the upper surface of the semiconductor wafer W is rapidly heated when the semiconductor wafer W is irradiated with flashes of light that are intense and have an extremely short irradiation time, a difference in temperature is caused between the upper and lower surfaces of the semiconductor wafer W, and the temperature on the upper surface of the semiconductor wafer W cannot be measured by the lower radiation thermometers 20.

The controller 3 calculates a maximum temperature to which the temperature on the upper surface of the semiconductor wafer W has reached at irradiation with flashes of light (step ST6). The temperature on the lower surface of the semiconductor wafer W is continuously measured by the upper radiation thermometer 25 or the lower radiation thermometers 20 at least from the time t2 when the temperature of the semiconductor wafer W reaches the certain temperature at preheating to the time t3 when the semiconductor wafer W is irradiated with flashes of light. At the preheating stage before irradiation with flashes of light, there is no difference in temperature between the upper and lower surfaces of the semiconductor wafer W, and the temperature on the lower surface of the semiconductor wafer W measured by the upper radiation thermometer 25 or the lower radiation thermometers 20 before irradiation with flashes of light is also the temperature on the upper surface. The controller 3 calculates a maximum reached temperature T2 on the upper surface by adding the raised temperature ΔT on the upper surface of the semiconductor wafer W measured by the upper radiation thermometer 25 at irradiation with flashes of light to the temperature (preheat temperature T1) on the lower surface of the semiconductor wafer W measured by the upper radiation thermometer 25 or the lower radiation thermometers 20 between the time t2 and the time t3 immediately before irradiation with flashes of light. The controller 3 may cause the display unit 33 to display the calculated maximum reached temperature T2. It is envisioned that the maximum reached temperature T2 will be 800° C. or more and 1100° C. or less, for example, and preferably will be 1000° C. or more and 1100° C. or less (1000° C. in the present embodiment).

The maximum reached temperature T2 on the upper surface of the semiconductor wafer W at irradiation with flashes of light can be calculated with accuracy by adding the raised temperature ΔT on the upper surface of the semiconductor wafer W measured by the upper radiation thermometer 25 to the temperature on the lower surface (=the temperature on the upper surface) of the semiconductor wafer W measured with accuracy by the upper radiation thermometer 25 or the lower radiation thermometers 20.

The halogen lamps HL are turned off at time t4 when a predetermined time has elapsed since the end of irradiation with flashes of light. The temperature of the semiconductor wafer W is thereby rapidly lowered from the preheat temperature T1. The temperature of the semiconductor wafer W being lowered is measured by the upper radiation thermometer 25 or the lower radiation thermometers 20, and a result of measurement is transmitted to the controller 3. The controller 3 monitors the result of measurement by the upper radiation thermometer 25 or the lower radiation thermometers 20 to determine whether the temperature of the semiconductor wafer W has been lowered to a predetermined temperature. After the temperature of the semiconductor wafer W has been lowered to the predetermined temperature or less, the pair of transfer arms 11 of the transfer mechanism 10 horizontally moves again from the withdrawal location to the transfer operation location and moves upward, so that the lift pins 12 protrude from the upper surface of the susceptor 74 to receive the semiconductor wafer W having been thermally processed from the susceptor 74. The transport opening 66 closed by the gate valve 185 is then opened, and the semiconductor wafer W mounted on the lift pins 12 is transported from the chamber 6 by the transport robot outside the apparatus to complete heating of the semiconductor wafer W (step S5).

According to a configuration as described above, the infrared sensors 24 can measure the temperature of the semiconductor wafer W while avoiding receiving light emitted from the halogen lamps HL using the light blocking member 201.

Since the wavelength region measurable by each of the infrared sensors 24 is the wavelength region capable of sufficiently being transmitted through the holding plate 75 consisting of quartz, light radiated from the lower surface of the semiconductor wafer W and then transmitted through the holding plate 75 can be received in a direction substantially perpendicular to the main surface of the semiconductor wafer W. Due to reduction in range of measurement of the temperature of the semiconductor wafer W by each of the infrared sensors 24 in addition to reception of a sufficient amount of light, accuracy of temperature measurement can be improved.

In-plane uniformity of the temperature of the semiconductor wafer W is evaluated by arranging the plurality of infrared sensors 24, and measuring the temperature of the semiconductor wafer W using each of the infrared sensors 24. Furthermore, in-plane uniformity of the temperature of the semiconductor wafer W can be improved by controlling output of the halogen lamps HL using the controller 3 so that the temperature at a plurality of locations of the semiconductor wafer W becomes uniform.

### Second Embodiment

A thermal processing apparatus according to the present embodiment will be described below. In description made below, components similar to those described in the above-mentioned embodiment bear the same reference signs, and detailed description thereof will be omitted as appropriate.

<Configuration of Thermal Processing Apparatus>

FIG. 13 is a cross-sectional view schematically showing a configuration of a thermal processing unit 160A according to the present embodiment.

As illustrated in FIG. 13, the thermal processing unit 160A is a flash lamp annealing apparatus for heating the semiconductor wafer W by irradiating the semiconductor wafer W with a flash of light in a thermal processing apparatus.

The thermal processing unit 160A includes a chamber 6A for containing the semiconductor wafer W, a flash heating unit 5A incorporating the plurality of flash lamps FL, and an LED heating unit 4A incorporating one or more LED lamps 210 for continuously heating the semiconductor wafer W. The flash heating unit 5A is provided on an upper side of the chamber 6A, and the LED heating unit 4A is provided on a lower side of the chamber 6A.

The LED heating unit 4A heats the semiconductor wafer W by irradiating a thermal processing space 65A with light from below the chamber 6A through a lower chamber window 64 using the plurality of LED lamps 210. That is to say, the surface on a lower side of the semiconductor wafer W opposing the LED lamps 210 is heated using the plurality of LED lamps 210. Each of the LED lamps 210 is a red LED, for example, and has a wavelength range having a peak wavelength of 380 nm or more and 780 nm or less (having a full width at half maximum of approximately 50 nm, for example).

The thermal processing unit 160A also includes, within the chamber 6A, the holding unit 7 for holding the semiconductor wafer W in the horizontal position and the transfer mechanism 10 for transferring the semiconductor wafer W between the holding unit 7 and the outside of the apparatus.

The thermal processing unit 160A further includes the controller 3 for controlling each operation mechanism provided in the LED heating unit 4A, the flash heating unit 5A, and the chamber 6A to perform thermal processing of the semiconductor wafer W.

The chamber 6A includes a tubular chamber side portion 261 and chamber windows of quartz attached to the top and bottom of the chamber side portion 261. The chamber side portion 261 has a substantially tubular shape with its top and bottom opened. The upper chamber window 63 is attached to an upper opening for blocking, and the lower chamber window 64 is attached to a lower opening for blocking. The upper chamber window 63 is disposed between the flash lamps FL and the semiconductor wafer W. The lower chamber window 64 is disposed between the LED lamps 210 and the susceptor 74.

The lower chamber window 64 forming a floor of the chamber 6A is a disk-shaped member including quartz, and functions as a quartz window for transmitting light from the LED heating unit 4A to the inside of the chamber 6A.

The reflective ring 68 is attached to an upper portion of an inner wall surface of the chamber side portion 261, and a reflective ring 69 is attached to a lower portion of the inner wall surface of the chamber side portion 261. The reflective ring 68 and the reflective ring 69 are each formed to be annular.

The reflective ring 69 on a lower side is attached by being fit to the chamber side portion 261 from below and fastened with screws, which are not illustrated. That is to say, the reflective ring 69 is removably attached to the chamber side portion 261.

A space inside the chamber 6A, that is, a space enclosed by the upper chamber window 63, the lower chamber window 64, the chamber side portion 261, the reflective ring 68, and the reflective ring 69 is defined as the thermal processing space 65A.

By attaching the reflective ring 68 and the reflective ring 69 to the chamber side portion 261, the recess 62 is formed in the inner wall surface of the chamber 6A. That is to say, the recess 62 surrounded by a central portion of the inner wall surface of the chamber side portion 261 to which the reflective ring 68 and the reflective ring 69 have not been attached, a lower end surface of the reflective ring 68, and an upper end surface of the reflective ring 69 is formed.

The recess 62 is formed in the inner wall surface of the chamber 6A to be annular along the horizontal direction, and surrounds the holding unit 7 for holding the semiconductor wafer W. The chamber side portion 261, the reflective ring 68, and the reflective ring 69 each include the metallic material (e.g., stainless steel) having high strength and excellent heat resistance.

The chamber side portion 261 has the transport opening (furnace mouth) 66 for transporting the semiconductor wafer W to and from the chamber 6A. The transport opening 66 is openable and closable by the gate valve 185. The transport opening 66 is connected in communication with the outer circumferential surface of the recess 62.

Furthermore, the chamber side portion 261 has the through hole 61a. The through hole 61a is the cylindrical hole for guiding the infrared light radiated from the upper surface of the semiconductor wafer W held by the susceptor 74, which will be described below, to the infrared sensor 29 of the upper radiation thermometer 25. The through hole 61a is inclined with respect to the horizontal direction so that the axis thereof in the direction of penetration intersects the main surface of the semiconductor wafer W held by the susceptor 74.

At least one infrared sensor 24A of a lower radiation thermometer 20A is provided at a bottom of a housing 41 of the LED heating unit 4A.

A wavelength region measurable by the infrared sensor 24A is 0.2 μm or more and 3 μm or less, preferably 0.9 μm or less, for example. The infrared sensor 24A has an optical axis substantially orthogonal to the main surface of the semiconductor wafer W held by the susceptor 74, and receives the infrared light radiated from the lower surface of the semiconductor wafer W. When the infrared sensor 24A receives the infrared light radiated from the lower surface of the semiconductor wafer W, a signal generated in response to reception of the light is transmitted to the temperature measurement unit 22 (FIG. 10) as in a case of the infrared sensor 24.

The at least one infrared sensor 24A is the pyroelectric sensor utilizing the pyroelectric effect, the thermopile utilizing the Seebeck effect, the thermal infrared sensor, such as the bolometer, utilizing the change in resistance of the semiconductor by heat, or the quantum infrared sensor, for example.

The transparent window 26 including the calcium fluoride material transmitting the infrared light in the wavelength region measurable by the upper radiation thermometer 25 is attached to the end of the through hole 61a facing the thermal processing space 65A.

The wavelength region measurable by the infrared sensor 24A of the lower radiation thermometer 20A is 0.2 μm or more and 3 μm or less, preferably 0.9 μm or less, for example, and thus at least partially overlaps a wavelength region of light emitted from the LED lamps 210.

In contrast to the wavelength region of the light emitted from the halogen lamps and the like, however, the wavelength region of the light emitted from the LED lamps 210 can be set to be limited to a relatively narrow wavelength region. The infrared sensor 24A thus filters out the wavelength region of the light emitted from the LED lamps 210 to avoid detecting the light emitted from the LED lamps 210.

FIG. 14 shows examples of an emission wavelength of the flash lamps FL, an emission wavelength of the halogen lamps HL, and an absorption coefficient of the semiconductor wafer W. The emission wavelength of the flash lamps FL (a solid line) and the emission wavelength of the halogen lamps HL (a thick line) follow a left vertical axis (intensity a.u.), and an absorption wavelength of the semiconductor wafer W (a dotted line) follows a right vertical axis (an absorption coefficient cm⁻¹). The horizontal axis represents a wavelength [nm].

In a case shown in FIG. 14, a wavelength indicating maximum emission intensity of the flash lamps FL is approximately 480 nm, and a wavelength indicating maximum emission intensity of the halogen lamps HL is approximately 1100 nm.

In such a case, the wavelength region of the light emitted from the LED lamps 210 can be set to 480 nm or more and 1100 nm or less, for example. Such a wavelength region corresponds to the absorption wavelength of the semiconductor wafer W, so that the semiconductor wafer W can effectively continuously be heated.

Furthermore, the wavelength region of the light emitted from the LED lamps 210 can be set to 900 nm or more and 1100 nm or less, for example, to avoid detection of the light from the LED lamps 210 by the infrared sensor 24A.

In order for the infrared sensor 24A to receive the infrared light radiated from the lower surface of the semiconductor wafer W, the light is required to be transmitted through the holding plate 75 located below the semiconductor wafer W. Since the wavelength region measurable by the infrared sensor 24A is 0.2 μm or more and 3 μm or less, preferably 0.9 μm or less, for example, in the present embodiment, the infrared sensor 24A can measure the light in the wavelength region capable of sufficiently being transmitted through the holding plate 75 consisting of quartz.

According to a configuration as described above, operation for measuring the temperature of the semiconductor wafer W as shown in an example of FIG. 11 can be performed using the infrared sensor 29 and the infrared sensor 24A. In this case, the infrared sensor 24A can measure the temperature of the semiconductor wafer W while avoiding detecting the light emitted from the LED lamps 210.

Use of the LED lamps 210 allows for preheating at a relatively low temperature of 200° C. or more and 500° C. or less, for example. Flash heating in which generation of a silicide or a germanide is envisioned after deposition of a metal film can thus be performed.

FIG. 15 is a cross-sectional view schematically showing a configuration of a thermal processing unit 160B according to the present embodiment.

As illustrated in FIG. 15, the thermal processing unit 160B is a flash lamp annealing apparatus for heating the semiconductor wafer W by irradiating the semiconductor wafer W with a flash of light in a thermal processing apparatus.

The thermal processing unit 160B includes the chamber 6A for containing the semiconductor wafer W, the heating unit 5 incorporating the plurality of flash lamps FL and the plurality of halogen lamps HL, and the LED heating unit 4A incorporating the plurality of LED lamps 210. The heating unit 5 is provided on the upper side of the chamber 6A, and the LED heating unit 4A is provided on the lower side of the chamber 6A.

According to a configuration as described above, the operation for measuring the temperature of the semiconductor wafer W as shown in the example of FIG. 11 can be performed using the infrared sensor 29 and the infrared sensor 24A. Since the heating unit 5 includes the plurality of flash lamps FL and the plurality of halogen lamps HL, a temperature rise rate of the semiconductor wafer W is increased, and control to improve in-plane uniformity of the temperature of the semiconductor wafer W is facilitated.

In a case were the structure illustrated in FIG. 15 includes the light blocking member 201 illustrated in FIG. 3, the light emitted from the halogen lamps HL is blocked by the light blocking member 201, and little light reaches the location below the holding unit 7. Direct reception of the light emitted from the halogen lamps HL by the infrared sensor 24A is thereby sufficiently suppressed.

### Third Embodiment

A thermal processing apparatus according to the present embodiment will be described below. In description made below, components similar to those described in the above-mentioned embodiments bear the same reference signs, and detailed description thereof will be omitted as appropriate.

<Configuration of Thermal Processing Apparatus>

FIG. 16 is a cross-sectional view schematically showing a configuration of a thermal processing unit 160C according to the present embodiment.

As illustrated in FIG. 16, the thermal processing unit 160C is a flash lamp annealing apparatus for heating the semiconductor wafer W by irradiating the semiconductor wafer W with a flash of light.

The thermal processing unit 160C includes the chamber 6 for containing the semiconductor wafer W and the heating unit 5 incorporating the plurality of flash lamps FL and the plurality of halogen lamps HL. The heating unit 5 is provided on the upper side of the chamber 6.

The thermal processing unit 160C also includes, within the chamber 6, a holding unit 7C for holding the semiconductor wafer W in the horizontal position and the transfer mechanism 10 for transferring the semiconductor wafer W between the holding unit 7C and the outside of the apparatus.

The thermal processing unit 160C further includes the controller 3 for controlling each operation mechanism provided in the heating unit 5 and the chamber 6 to perform thermal processing of the semiconductor wafer W.

The chamber 6 includes the chamber housing 61 and the upper chamber window 63 of quartz attached to the upper surface of the chamber housing 61 for blocking. The reflective ring 68 is attached to the upper portion of the inner wall surface of the chamber housing 61.

The space inside the chamber 6, that is, the space enclosed by the upper chamber window 63, the chamber housing 61, and the reflective ring 68 is defined as the thermal processing space 65.

By attaching the reflective ring 68 to the chamber housing 61, the recess 62 is formed in the inner wall surface of the chamber 6. The recess 62 is formed in the inner wall surface of the chamber 6 to be annular along the horizontal direction, and surrounds the holding unit 7C for holding the semiconductor wafer W.

The chamber housing 61 has the transport opening (furnace mouth) 66 for transporting the semiconductor wafer W to and from the chamber 6.

Furthermore, the chamber housing 61 has the through hole 61a and the at least one through hole 61b (the plurality of through holes 61b in the present embodiment). The through hole 61a is the cylindrical hole for guiding the infrared light radiated from the upper surface of the semiconductor wafer W held by a susceptor 74C, which will be described below, to the infrared sensor 29 of the upper radiation thermometer 25. On the other hand, the plurality of through holes 61b are the cylindrical holes for guiding the infrared light radiated from the lower surface of the semiconductor wafer W to infrared sensors 24C of the lower radiation thermometers 20. The at least one infrared sensor 24C (the plurality of infrared sensors 24C in the present embodiment) is the pyroelectric sensor utilizing the pyroelectric effect, the thermopile utilizing the Seebeck effect, the thermal infrared sensor, such as the bolometer, utilizing the change in resistance of the semiconductor by heat, or the quantum infrared sensor, for example.

A wavelength region measurable by each of the infrared sensors 24C is 5 μm or more and 6.5 μm or less, for example. The infrared sensors 24C arranged on the lower side of the semiconductor wafer W have optical axes substantially orthogonal to the main surface of the semiconductor wafer W held by the susceptor 74C consisting of quartz, and receive the infrared light radiated from the lower surface of the semiconductor wafer W.

The transparent window 26 including the calcium fluoride material transmitting the infrared light in the wavelength region measurable by the upper radiation thermometer 25 is attached to the end of the through hole 61a facing the thermal processing space 65. The transparent windows 21 including the barium fluoride material transmitting the infrared light in the wavelength region measurable by the lower radiation thermometers 20 are attached to the ends of the through holes 61b facing the thermal processing space 65.

FIG. 17 is a perspective view illustrating appearance of the holding unit 7C as a whole. The holding unit 7C includes the base ring 71, the connectors 72, and the susceptor 74C. The base ring 71, the connectors 72, and the susceptor 74C each include quartz. That is to say, the holding unit 7C as a whole includes quartz.

The susceptor 74C includes a holding plate 75C, the guide ring 76, and the plurality of support pins 77. The holding plate 75C of the susceptor 74C has through holes 220 vertically passing through the holding plate 75C. The through holes 220 are each circular, for example, but the shape of the through holes 220 is not limited to this shape. The number of through holes 220 may be any number, but preferably corresponds to the number of infrared sensors 24C arranged below the holding unit 7C. The through holes 220 are formed at locations where the through holes 220 overlap the infrared sensors 24C in plan view (i.e., locations where the through holes 220 intersect optical axes of the infrared sensors 24C and locations around the locations).

The susceptor 74C in the present embodiment supports the semiconductor wafer W from below, but the susceptor 74C may support the semiconductor wafer W in another manner (e.g., may laterally clamp the semiconductor wafer W) as long as the susceptor 74C can hold the semiconductor wafer W, and is hollow at locations where the susceptor 74C intersects the optical axes of the infrared sensors 24C (and locations around the locations).

According to a configuration as described above, the operation for measuring the temperature of the semiconductor wafer W as shown in the example of FIG. 11 can be performed using the infrared sensor 29 and the infrared sensors 24C. In this case, since the holding plate 75C has the through holes 220 at locations where the holding plate 75C intersects the optical axes of the infrared sensors 24C, the infrared sensors 24C can receive the light radiated from the lower surface of the semiconductor wafer W in the direction substantially perpendicular to the main surface of the semiconductor wafer W even if the wavelength region measurable by the infrared sensors 24C is not a wavelength region of light transmitted through the holding plate 75C consisting of quartz.

<Effects Produced by Embodiments Described Above>

Examples of effects produced by the embodiments described above will be described next. In description made below, the effects will be described based on a specific configuration having been described in any of the embodiments described above, but the specific configuration may be replaced by another specific configuration having been described in the description of the present application to the extent that similar effects are produced.

The replacement may be made among the plurality of embodiments. That is to say, configurations having been described in different embodiments may be combined with each other to produce similar effects.

According to the embodiments described above, the thermal processing apparatus includes the chamber 6, a support, the flash lamp FL, a continuous illumination lamp, the light blocking member 201, and at least one radiation thermometer. The support herein corresponds to the susceptor 74, for example. The continuous illumination lamp corresponds to each of the halogen lamps HL, for example. The radiation thermometer corresponds to each of the infrared sensors 24, for example. The chamber 6 contains the substrate. The substrate herein corresponds to the semiconductor wafer W, for example. The susceptor 74 includes quartz. The susceptor 74 supports the semiconductor wafer W from a first side within the chamber 6. The first side herein corresponds to the lower side, for example. The flash lamp FL is disposed on a second side of the semiconductor wafer W opposite the lower side. The second side herein corresponds to the upper side, for example. The flash lamp FL heats the semiconductor wafer W by irradiating the semiconductor wafer W with a flash of light. The halogen lamp HL is disposed on the upper side of the semiconductor wafer W. The halogen lamp HL continuously heats the semiconductor wafer W. The light blocking member 201 separates the lower side and the upper side of the semiconductor wafer W within the chamber 6, and is disposed to surround the semiconductor wafer W in plan view. The infrared sensors 24 are arranged on the lower side of the semiconductor wafer W. The infrared sensors 24 each measure the temperature of the semiconductor wafer W. The infrared sensors 24 each measure the temperature of the semiconductor wafer W by receiving light at a wavelength capable of being transmitted through the susceptor 74.

According to such a configuration, the infrared sensors 24 can sufficiently receive the light radiated from the lower surface of the semiconductor wafer W, so that accuracy of measurement of the temperature of the semiconductor wafer W can be increased. Specifically, the wavelength region measurable by each of the infrared sensors 24 is the wavelength region capable of sufficiently being transmitted through the susceptor 74 including quartz, so that the light radiated from the lower surface of the semiconductor wafer W and then transmitted through the susceptor 74 can be received in the direction substantially perpendicular to the main surface of the semiconductor wafer W. Due to reduction in range of measurement of the temperature of the semiconductor wafer W by each of the infrared sensors 24 in addition to reception of a sufficient amount of light, accuracy of temperature measurement can be improved. The light blocking member 201 can avoid reception of the light emitted from the halogen lamps HL by the infrared sensors 24. Furthermore, in a wavelength region of 0.9 μm or less, for example, a change in emissivity due to the temperature of the semiconductor wafer W is small, and thus accuracy of temperature measurement can be improved. Improvement in accuracy of measurement of the temperature of the semiconductor wafer W can improve accuracy of control of the temperature of the semiconductor wafer W, resulting in suppression of cracking of the semiconductor wafer W and the like.

Similar effects can be produced in a case where another configuration having not been described in the description of the present application is added to the above-mentioned configuration as appropriate, that is, in a case where another configuration in the description of the present application having not been referred to as the above-mentioned configuration is added to the above-mentioned configuration as appropriate.

According to the embodiments described above, the susceptor 74 including quartz and being for supporting the semiconductor wafer W from the lower side, the flash lamp FL disposed on the upper side of the semiconductor wafer W opposite the lower side and being for heating the semiconductor wafer W by irradiating the semiconductor wafer W with a flash of light, the at least one LED lamp 210 disposed on the lower side of the semiconductor wafer W and being for continuously heating the semiconductor wafer W, the quartz window including quartz and disposed between the flash lamp FL and the semiconductor wafer W and the quartz window including quartz and disposed between the LED lamp 210 and the susceptor 74, and the least one radiation thermometer disposed on the lower side of the semiconductor wafer W and being for measuring the temperature of the semiconductor wafer W are included. The quartz windows herein correspond to the upper chamber window 63 and the lower chamber window 64, for example. The radiation thermometer corresponds to the infrared sensor 24A, for example. The infrared sensor 24A measures the temperature of the semiconductor wafer W by receiving the light at the wavelength capable of being transmitted through the susceptor 74.

According to such a configuration, the infrared sensor 24A can sufficiently receive the light radiated from the lower surface of the semiconductor wafer W, so that accuracy of measurement of the temperature of the semiconductor wafer W can be increased. Specifically, the wavelength region measurable by the infrared sensor 24A is the wavelength region capable of sufficiently being transmitted through the susceptor 74 including quartz, so that the light radiated from the lower surface of the semiconductor wafer W and then transmitted through the susceptor 74 can be received in the direction substantially perpendicular to the main surface of the semiconductor wafer W. Due to reduction in range of measurement of the temperature of the semiconductor wafer W by the infrared sensor 24A in addition to reception of a sufficient amount of light, accuracy of temperature measurement can be improved. The infrared sensor 24A filters out the wavelength region of the light emitted from the LED lamps 210 to avoid detecting the light emitted from the LED lamps 210. Furthermore, in the wavelength region of 0.9 μm or less, for example, the change in emissivity due to the temperature of the semiconductor wafer W is small, and thus accuracy of temperature measurement can be improved.

Similar effects can be produced in a case where another configuration having not been described in the description of the present application is added to the above-mentioned configuration as appropriate, that is, in a case where another configuration in the description of the present application having not been referred to as the above-mentioned configuration is added to the above-mentioned configuration as appropriate.

According to the embodiment described above, the infrared sensor 24A excludes the emission wavelength of the LED lamps 210 from the wavelength at which the light is received. According to such a configuration, detection of the light emitted from the LED lamps 210 by the infrared sensor 24A can be avoided.

According to the embodiment described above, the plurality of LED lamps 210 are arranged opposite the surface of the semiconductor wafer W on the lower side. According to such a configuration, the lower surface of the semiconductor wafer W as a whole can uniformly be heated using the plurality of LED lamps 210.

According to the embodiments described above, the thermal processing apparatus includes the halogen lamp HL disposed on the upper side of the semiconductor wafer W and being for continuously heating the semiconductor wafer W. According to such a configuration, the heating unit 5 includes the plurality of flash lamps FL and the plurality of halogen lamps HL, so that the temperature rise rate of the semiconductor wafer W is increased, and control to improve in-plane uniformity of the temperature of the semiconductor wafer W is facilitated.

According to the embodiment described above, each of the LED lamps 210 continuously heats the semiconductor wafer W by irradiating the semiconductor wafer W with directional light at or above the wavelength indicating the maximum emission intensity of the flash lamp FL and at or below the wavelength indicating the maximum emission intensity of the halogen lamp HL. According to such a configuration, the semiconductor wafer W can effectively continuously be heated.

According to the embodiment described above, the support including quartz and being for supporting the semiconductor wafer W, the flash lamp FL disposed on the upper side of the semiconductor wafer W opposite the lower side and being for heating the semiconductor wafer W by irradiating the semiconductor wafer W with a flash of light, the halogen lamp HL disposed on the upper side of the semiconductor wafer W and being for continuously heating the semiconductor wafer W, and the least one radiation thermometer disposed on the lower side of the semiconductor wafer W and for measuring the temperature of the semiconductor wafer W are included. The support herein corresponds to the susceptor 74C, for example. The radiation thermometer corresponds to each of the infrared sensors 24C, for example. The susceptor 74C is disposed at least except at a location where the susceptor 74C intersects an optical axis of each of the infrared sensors 24C.

According to such a configuration, the infrared sensors 24C can sufficiently receive the light radiated from the lower surface of the semiconductor wafer W, so that accuracy of measurement of the temperature of the semiconductor wafer W can be increased. Specifically, the holding plate 75C has the through holes 220 at the locations where the holding plate 75C intersects the optical axes of the infrared sensors 24C, so that the infrared sensors 24C can receive the light radiated from the lower surface of the semiconductor wafer W in the direction substantially perpendicular to the main surface of the semiconductor wafer W. Due to reduction in range of measurement of the temperature of the semiconductor wafer W by each of the infrared sensors 24C in addition to reception of a sufficient amount of light, accuracy of temperature measurement can be improved.

Similar effects can be produced in a case where another configuration having not been described in the description of the present application is added to the above-mentioned configuration as appropriate, that is, in a case where another configuration in the description of the present application having not been referred to as the above-mentioned configuration is added to the above-mentioned configuration as appropriate.

According to the embodiment described above, the susceptor 74C has each of the through holes 220 at the location where the susceptor 74C intersects the optical axis of each of the infrared sensors 24C. According to such a configuration, the infrared sensors 24C can receive the light radiated from the lower surface of the semiconductor wafer W in the direction substantially perpendicular to the main surface of the semiconductor wafer W even if the wavelength region measurable by the infrared sensors 24C is not the wavelength region of light transmitted through the holding plate 75C including quartz.

According to the embodiment described above, the optical axis of each of the infrared sensors 24 (or the optical axis of the infrared sensor 24A) is orthogonal to the main surface of the semiconductor wafer W. According to such a configuration, accuracy of temperature measurement can be improved due to reduction in range of measurement of the temperature of the semiconductor wafer W by each of the infrared sensors. In-plane uniformity of the temperature of the semiconductor wafer W is evaluated by arranging the plurality of infrared sensors, and measuring the temperature of the semiconductor wafer W using each of the infrared sensors. Furthermore, in-plane uniformity of the temperature of the semiconductor wafer W can be improved by controlling output of the halogen lamps HL using the controller 3 so that the temperature at the plurality of locations of the semiconductor wafer W becomes uniform.

According to the embodiment described above, the wavelength region measurable by each of the infrared sensors 24 (or the infrared sensor 24A) is 3 μm or less. According to such a configuration, the wavelength region measurable by each of the infrared sensors is the wavelength region capable of sufficiently being transmitted through the susceptor including quartz, so that the light radiated from the lower surface of the semiconductor wafer W and then transmitted through the susceptor can be received in the direction substantially perpendicular to the main surface of the semiconductor wafer W. Due to reduction in range of measurement of the temperature of the semiconductor wafer W by each of the infrared sensors 24 in addition to reception of a sufficient amount of light, accuracy of temperature measurement can be improved. Furthermore, in the wavelength region of 0.9 μm or less, for example, the change in emissivity due to the temperature of the semiconductor wafer W is small, and thus accuracy of temperature measurement can be improved.

According to the embodiments described above, the continuous illumination lamp is the halogen lamp. According to such a configuration, the halogen lamps HL are arranged above the semiconductor wafer W, so that direct reception of the light emitted from the halogen lamps HL by each of the infrared sensors 24 for measuring the temperature of the semiconductor wafer W from below the semiconductor wafer W is thereby suppressed.

<Modifications of Embodiments Described Above>

In the embodiments described above, material properties of, materials for, dimensions of, shapes of, a relative positional relationship among, or conditions for performance of components are sometimes described, but they are each one example in all aspects, and are not limited to those described in the description of the present application.

Numerous modifications not having been described and the equivalent can be devised within the scope of the technology disclosed in the description of the present application. For example, a case where at least one component is modified, added, or omitted is included and, further, a case where at least one component in at least one embodiment is extracted to be combined with components in another embodiment are included.

In a case where a name of a material and the like are described in the above-mentioned embodiment without being particularly designated, an alloy and the like containing an additive in addition to the material may be included unless any contradiction occurs.

While the invention has been shown and described in detail, the foregoing description is in all aspects illustrative and not restrictive. It is therefore understood that numerous modifications and variations can be devised without departing from the scope of the invention.

What is claimed is:

1. A thermal processing apparatus comprising:
a chamber for containing a substrate;
a support for supporting the substrate from a first side within the chamber, the support comprising quartz;
a flash lamp for heating the substrate by irradiating the substrate with a flash of light, the flash lamp being disposed on a second side of the substrate opposite the first side;
a continuous illumination lamp for continuously heating the substrate, the continuous illumination lamp being disposed on the second side of the substrate;
a light blocking member separating the first side and the second side of the substrate within the chamber, the light blocking member being disposed to surround the substrate in plan view; and
at least one radiation thermometer for measuring a temperature of the substrate, the radiation thermometer being disposed on the first side of the substrate, wherein
the radiation thermometer measures the temperature of the substrate by receiving light at a wavelength capable of being transmitted through the support.

2. A thermal processing apparatus comprising:
a support for supporting a substrate from a first side, the support comprising quartz;
a flash lamp for heating the substrate by irradiating the substrate with a flash of light, the flash lamp being disposed on a second side of the substrate opposite the first side;
at least one LED lamp for continuously heating the substrate, the LED lamp being disposed on the first side of the substrate;
a quartz window disposed between the flash lamp and the substrate and a quartz window disposed between the LED lamp and the support, the quartz windows comprising quartz; and
at least one radiation thermometer for measuring a temperature of the substrate, the radiation thermometer being disposed on the first side of the substrate, wherein
the radiation thermometer measures the temperature of the substrate by receiving light at a wavelength capable of being transmitted through the support.

3. The thermal processing apparatus according to claim 2, wherein
the radiation thermometer excludes an emission wavelength of the LED lamp from the wavelength at which the light is received.

4. The thermal processing apparatus according to claim 2, wherein
the LED lamp comprises a plurality of LED lamps arranged opposite a surface of the substrate on the first side.

5. The thermal processing apparatus according to claim 2, further comprising
a continuous illumination lamp for continuously heating the substrate, the continuous illumination lamp being disposed on the second side of the substrate.

6. The thermal processing apparatus according to claim 5, wherein
the LED lamp continuously heats the substrate by irradiating the substrate with directional light at or above a wavelength indicating maximum emission intensity of the flash lamp and at or below a wavelength indicating maximum emission intensity of the continuous illumination lamp.

7. A thermal processing apparatus comprising:
a support for supporting a substrate, the support comprising quartz;
a flash lamp for heating the substrate by irradiating the substrate with a flash of light, the flash lamp being disposed on a second side of the substrate opposite a first side;
a continuous illumination lamp for continuously heating the substrate, the continuous illumination lamp being disposed on the second side of the substrate; and
at least one radiation thermometer for measuring a temperature of the substrate, the radiation thermometer being disposed on the first side of the substrate, wherein
the support is disposed at least except at a location where the support intersects an optical axis of the radiation thermometer.

8. The thermal processing apparatus according to claim 7, wherein
the support has a through hole at the location where the support intersects the optical axis of the radiation thermometer.

9. The thermal processing apparatus according to claim 1, wherein
an optical axis of the radiation thermometer is orthogonal to a main surface of the substrate.

10. The thermal processing apparatus according to claim 1, wherein
a wavelength region measurable by the radiation thermometer is 3 μm or less.

11. The thermal processing apparatus according to claim 1, wherein
the continuous illumination lamp is a halogen lamp.

12. The thermal processing apparatus according to claim 2, wherein
an optical axis of the radiation thermometer is orthogonal to a main surface of the substrate.

13. The thermal processing apparatus according to claim 7, wherein
the optical axis of the radiation thermometer is orthogonal to a main surface of the substrate.

14. The thermal processing apparatus according to claim 2, wherein
a wavelength region measurable by the radiation thermometer is 3 μm or less.

15. The thermal processing apparatus according to claim 7, wherein
a wavelength region measurable by the radiation thermometer is 3 μm or less.

16. The thermal processing apparatus according to claim 7, wherein
the continuous illumination lamp is a halogen lamp.
